(19) United States
(12) Patent Application Publication
(10) Pub. No.: US 2019/0212067 A1
(43) Pub. Date: Jul. 11, 2019

(54) MULTI-OUTLET-INLET MULTILAYERED LIQUID-COOLING HEAT DISSIPATION STRUCTURE

(71) Applicant: ASIA VITAL COMPONENTS CO., LTD., New Taipei City (TW)

(72) Inventor: Wen-Ji Lan, New Taipei City (TW)

(21) Appl. No.: 15/867,718

(22) Filed: Jan. 11, 2018

(51) Int. Cl. F28D 9/00; F28F 3/14; F28F 3/06; G06F 1/20; H05K 7/20

(52) U.S. Cl. CPC F28D 9/0068; F28F 3/14; F28F 3/06; F28F 2210/10; H05K 7/20263; G06F 2200/201; G06F 1/20

(57) ABSTRACT

A multi-outlet-inlet laminated liquid-cooling heat dissipation structure includes a top plate, a bottom plate mated with the top plate, a substrate disposed between the top plate and the bottom plate and multiple communication passages. The substrate has an upper face, a lower face and at least one communication unit. The top plate and the upper face together define an upper liquid chamber. The bottom plate and the lower face together define a lower liquid chamber. The at least one communication unit passes through the substrate between the upper and lower faces to communicate with the upper and lower liquid chambers for a working fluid to flow through. Each communication passage has a communication opening in communication with the upper and lower liquid chambers as an inlet or an outlet of the working fluid.

### BACKGROUND OF THE INVENTION

### 1. Field of the Invention

The present invention relates generally to a heat dissipation structure, and more particularly to a multi-outlet-inlet laminated liquid-cooling heat dissipation structure in which pumps are disposed.

### 2. Description of the Related Art

Currently, liquid-cooling heat dissipation devices are widely applied to communication, electrical implements, vehicle industry, instruction, etc. for manufacturing various parts and products. When a computer operates, many internal components of the computer will generate high heat. Therefore, a good heat dissipation system is a critical factor determining the operation performance and reliability of the computer. Among all the heat generation components, the central processing unit (CPU) and the graphics processing unit (GPU) generally have higher working loads and the heat dissipation issue of these two components is the most knotty problem. Especially, the pictures of various current computer games have become finer and finer and the function of the computer-assistant graphics software has become stronger and stronger. In operation, such software often makes the central processing unit and the graphics processing unit in a highly loaded state. As a result, the central processing unit and the graphics processing unit will generate high heat. The heat must be effectively dissipated. Otherwise, in a minor case, the performance of the central processing unit and the graphics processing unit will be deteriorated, while in a serious case, the central processing unit and the graphics processing unit may be damaged or the lifetime of the central processing unit and the graphics processing unit will be shortened.

Please refer to FIG. 1. In order to lower the working temperature of the heat generation electronic component, a common commercially available water-cooling device includes a water-cooling radiator 1, two water conduits 51, a water-cooling head 5 in contact with a heat generation component (such as central processing unit) and a pump 6. The water conduits 51 are connected between the water-cooling radiator 1 and the water-cooling head 5. The pump 6 serves to drive the water-cooling liquid (or so-called working fluid) to flow to the water-cooling radiator 1 to dissipate the heat and continuously circulate the working fluid to cool the heat generation component and quickly dissipate the heat. The conventional water-cooling radiator 1 is composed of multiple radiating fins 11, multiple flat tubes 12 and two lateral water tanks 13. The radiating fins 11 are disposed between the straight flat tubes 12. The two lateral water tanks 13, the radiating fins 11 and two sides of the straight flat tubes 12 are soldered with each other so that the two lateral water tanks 13, the radiating fins 11 and the straight flat tubes 12 are connected to form the water-cooling radiator 1. A water inlet 131 and a water outlet 132 are disposed on one of the lateral water tanks 13. The water inlet 131 and the water outlet 132 are respectively connected with the two water conduits 51.

After the working fluid flows from the water inlet 13 into one of the lateral water tanks 13, the working fluid quickly flows through the straight flat tubes 12 into the other lateral water tank 13. Then, the working fluid is exhausted from the water outlet 132. Therefore, the flowing time of the working fluid carrying the heat within the water-cooling radiator 1 is quite short so that the heat exchange time of the working fluid carrying the heat with the water-cooling radiator 1 is not long. As a result, the heat dissipation effect of the conventional water-cooling radiator for the working fluid carrying the heat is poor. This leads to poor heat dissipation efficiency. Moreover, the entire structure of the conventional water-cooling radiator cannot be adjusted or changed in adaptation to the internal space of an electronic device. Therefore, when installed in an electronic device (such as a computer or a server), the conventional water-cooling radiator necessitates an independent space inside the electronic device for placing the conventional water-cooling radiator.

It is therefore tried by the applicant to provide a multi-outlet-inlet liquid-cooling heat dissipation structure to solve the above problems existing in the conventional water-cooling device.

### SUMMARY OF THE INVENTION

It is therefore a primary object of the present invention to provide a multi-outlet-inlet laminated liquid-cooling heat dissipation structure, which has better heat dissipation performance.

It is a further object of the present invention to provide the above multi-outlet-inlet laminated liquid-cooling heat dissipation structure, in which two liquid-containing plate bodies are stacked at an interval. Each of the liquid-containing plate bodies has a liquid chamber in which a flow way is disposed. Accordingly, the flowing time of a working fluid within the multi-outlet-inlet laminated liquid-cooling heat dissipation structure is effectively increased (or prolonged). Therefore, the heat dissipation efficiency is effectively enhanced.

To achieve the above and other objects, the multi-outlet-inlet laminated liquid-cooling heat dissipation structure of the present invention includes a top plate, a bottom plate mated with the top plate and a substrate disposed between the top plate and the bottom plate. The substrate has an upper face, a lower face and at least one communication unit. The top plate and the upper face together define an upper liquid chamber. The bottom plate and the lower face together define a lower liquid chamber. The at least one communication unit passes through the substrate between the upper and lower faces to communicate with the upper and lower liquid chambers for a working fluid to flow through. The multi-outlet-inlet laminated liquid-cooling heat dissipation structure further includes multiple communication passages. Each communication passage has a communication opening respectively in communication with the upper and lower liquid chambers as an inlet or an outlet of the working fluid.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective view of a conventional water-cooling device;

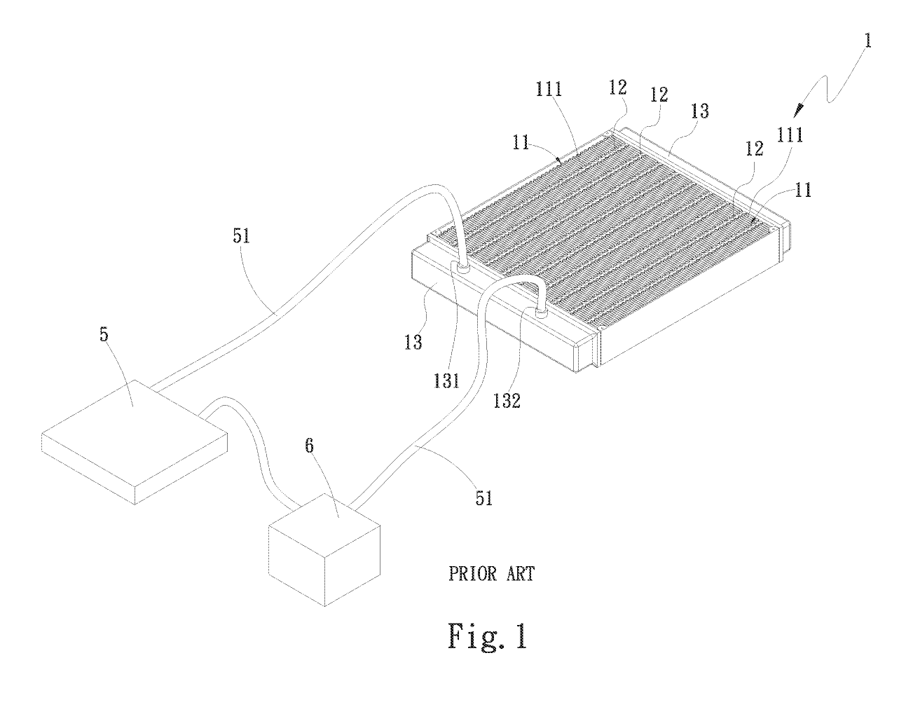

FIG. 2A is a perspective exploded view of a first embodiment of the multi-outlet-inlet laminated liquid-cooling heat dissipation structure of the present invention;

FIG. 2B is a perspective exploded view of the first embodiment of the multi-outlet-inlet laminated liquid-cooling heat dissipation structure of the present invention, seen from another angle;

FIG. 2C is a perspective assembled view of the first embodiment of the multi-outlet-inlet laminated liquid-cooling heat dissipation structure of the present invention;

FIG. 2D is a partially sectional view of the first embodiment of the multi-outlet-inlet laminated liquid-cooling heat dissipation structure of the present invention;

FIG. 3A is a perspective exploded view of a modified embodiment of the first embodiment of the multi-outlet-inlet laminated liquid-cooling heat dissipation structure of the present invention;

FIG. 3B is a perspective exploded view of another modified embodiment of the first embodiment of the multi-outlet-inlet laminated liquid-cooling heat dissipation structure of the present invention;

FIG. 3C is a partially sectional view of another modified embodiment of the first embodiment of the multi-outlet-inlet laminated liquid-cooling heat dissipation structure of the present invention;

FIG. 3D is a partially sectional view of another modified embodiment of the first embodiment of the multi-outlet-inlet laminated liquid-cooling heat dissipation structure of the present invention;

FIG. 3E is a perspective exploded view of another modified embodiment of the first embodiment of the multi-outlet-inlet laminated liquid-cooling heat dissipation structure of the present invention;

FIG. 3F is a perspective exploded view of another modified embodiment of the first embodiment of the multi-outlet-inlet laminated liquid-cooling heat dissipation structure of the present invention;

FIG. 3G is a top sectional view of another modified embodiment of the first embodiment of the multi-outlet-inlet laminated liquid-cooling heat dissipation structure of the present invention;

FIG. 4A is a perspective exploded view of another modified embodiment of the first embodiment of the multi-outlet-inlet laminated liquid-cooling heat dissipation structure of the present invention;

FIG. 4B is a perspective exploded view of another modified embodiment of the first embodiment of the multi-outlet-inlet laminated liquid-cooling heat dissipation structure of the present invention;

FIG. 4C is a perspective exploded view of another modified embodiment of the first embodiment of the multi-outlet-inlet laminated liquid-cooling heat dissipation structure of the present invention;

FIG. 4D is a perspective assembled view of another modified embodiment of the first embodiment of the multi-outlet-inlet laminated liquid-cooling heat dissipation structure of the present invention;

FIG. 5A is a perspective exploded view of a second embodiment of the multi-outlet-inlet laminated liquid-cooling heat dissipation structure of the present invention;

FIG. 5B is a perspective exploded view of the second embodiment of the multi-outlet-inlet laminated liquid-cooling heat dissipation structure of the present invention, seen from another angle;

FIG. 5C is a perspective assembled view of the second embodiment of the multi-outlet-inlet laminated liquid-cooling heat dissipation structure of the present invention;

FIG. 5D is a perspective exploded view of a modified embodiment of the second embodiment of the multi-outlet-inlet laminated liquid-cooling heat dissipation structure of the present invention;

FIG. 5E is a perspective exploded view of another modified embodiment of the second embodiment of the multi-outlet-inlet laminated liquid-cooling heat dissipation structure of the present invention;

FIG. 5F is a perspective exploded view of another modified embodiment of the second embodiment of the multi-outlet-inlet laminated liquid-cooling heat dissipation structure of the present invention;

FIG. 5G is a perspective exploded view of another modified embodiment of the second embodiment of the multi-outlet-inlet laminated liquid-cooling heat dissipation structure of the present invention;

FIG. 6A is a perspective exploded view of a third embodiment of the multi-outlet-inlet laminated liquid-cooling heat dissipation structure of the present invention;

FIG. 6B is a perspective exploded view of the third embodiment of the multi-outlet-inlet laminated liquid-cooling heat dissipation structure of the present invention, seen from another angle;

FIG. 6C is a perspective assembled view of the third embodiment of the multi-outlet-inlet laminated liquid-cooling heat dissipation structure of the present invention;

FIG. 6D is a perspective exploded view of a modified embodiment of the third embodiment of the multi-outlet-inlet laminated liquid-cooling heat dissipation structure of the present invention;

FIG. 6E is a perspective exploded view of another modified embodiment of the third embodiment of the multi-outlet-inlet laminated liquid-cooling heat dissipation structure of the present invention;

FIG. 6F is a partially sectional view of another modified embodiment of the third embodiment of the multi-outlet-inlet laminated liquid-cooling heat dissipation structure of the present invention;

FIG. 6G is a partially sectional view of another modified embodiment of the third embodiment of the multi-outlet-inlet laminated liquid-cooling heat dissipation structure of the present invention;

FIG. 7A is a perspective exploded view of a fourth embodiment of the multi-outlet-inlet laminated liquid-cooling heat dissipation structure of the present invention;

FIG. 7B is a perspective exploded view of the fourth embodiment of the multi-outlet-inlet laminated liquid-cooling heat dissipation structure of the present invention, seen from another angle;

FIG. 7C is a perspective assembled view of the fourth embodiment of the multi-outlet-inlet laminated liquid-cooling heat dissipation structure of the present invention;

FIG. 7D is a perspective exploded view of a modified embodiment of the fourth embodiment of the multi-outlet-inlet laminated liquid-cooling heat dissipation structure of the present invention;

FIG. 7E is a perspective exploded view of another modified embodiment of the fourth embodiment of the multi-outlet-inlet laminated liquid-cooling heat dissipation structure of the present invention;

FIG. 7F is a partially sectional view of another modified embodiment of the fourth embodiment of the multi-outlet-inlet laminated liquid-cooling heat dissipation structure of the present invention; and

FIG. 7G is a partially sectional view of another modified embodiment of the fourth embodiment of the multi-outlet-inlet laminated liquid-cooling heat dissipation structure of the present invention.

### DETAILED DESCRIPTION OF THE PREFERRED EMBODIMENTS

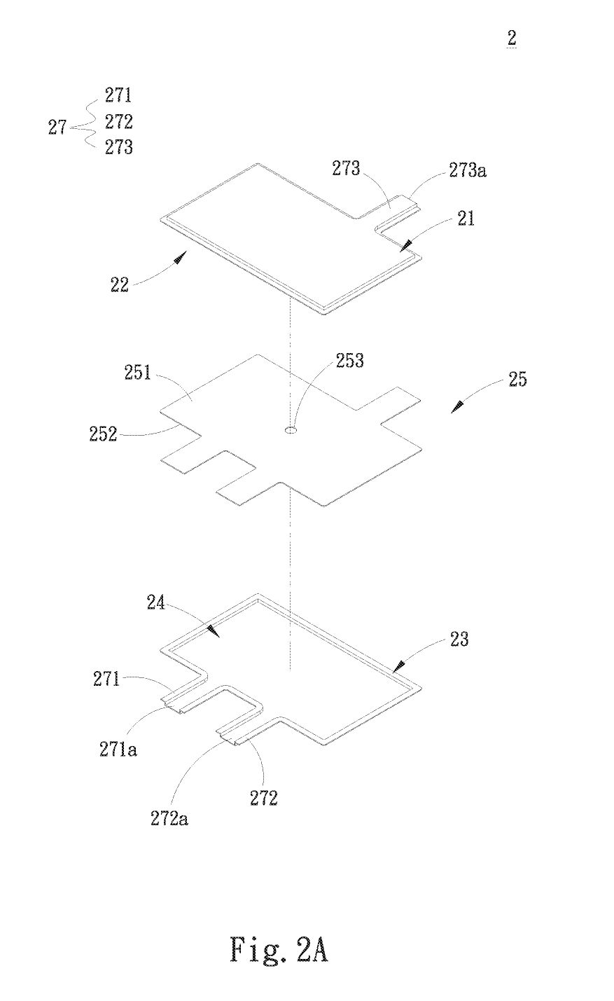

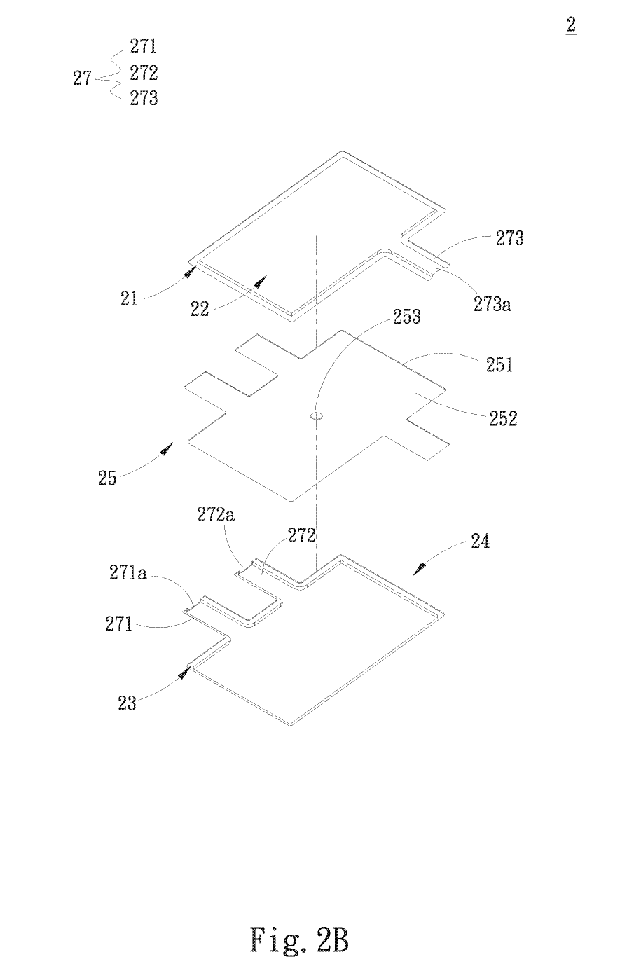

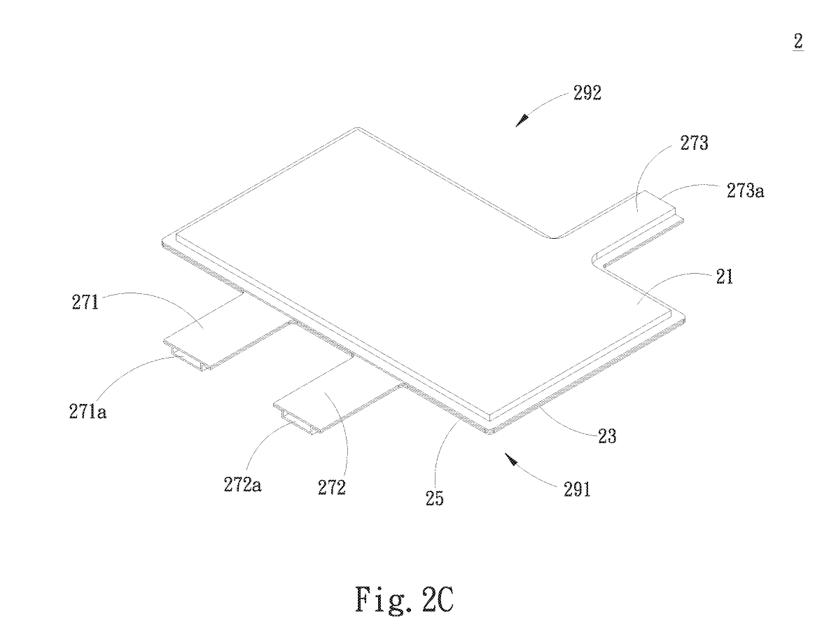

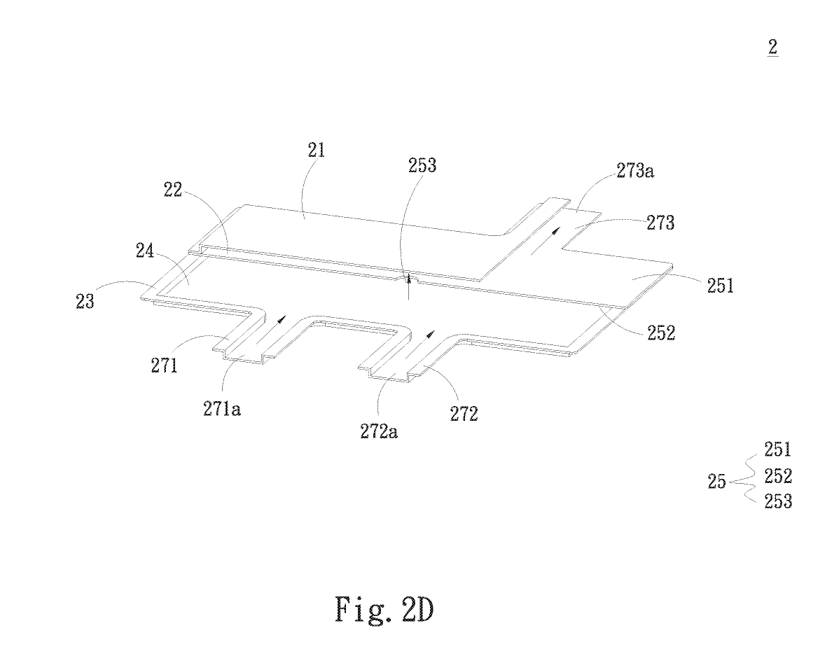

Please refer to FIGS. 2A to 2D. FIG. 2A is a perspective exploded view of a first embodiment of the multi-outlet-inlet laminated liquid-cooling heat dissipation structure of the present invention. FIG. 2B is a perspective exploded view of the first embodiment of the multi-outlet-inlet laminated liquid-cooling heat dissipation structure of the present invention, seen from another angle. FIG. 2C is a perspective assembled view of the first embodiment of the multi-outlet-inlet laminated liquid-cooling heat dissipation structure of the present invention. FIG. 2D is a partially sectional view of the first embodiment of the multi-outlet-inlet laminated liquid-cooling heat dissipation structure of the present invention. As shown in FIGS. 2A and 2B, the multi-outlet-inlet laminated liquid-cooling heat dissipation structure 2 of the present invention includes a top plate 21, a bottom plate 23, a substrate 25 and multiple communication passages 27.

In this embodiment, the bottom plate 23 is mated with the top plate 21. The substrate 25 is disposed between the top plate 21 and the bottom plate 23. The substrate 25 has an upper face 251, a lower face 252 and at least one communication unit 253. The top plate 21 and the upper face 251 together define an upper liquid chamber 22. The bottom plate 23 and the lower face 252 together define a lower liquid chamber 24. The at least one communication unit 253 passes through the substrate 25 between the upper and lower faces 251, 252 to communicate with the upper and lower liquid chambers 22, 24 for a working fluid to flow through. Each communication passage 27 has a communication opening respectively in communication with the upper and lower liquid chambers 22, 24.

In this embodiment, there is one communication unit 253 in communication with the upper and lower liquid chambers 22, 24. The communication passages 27 include a first communication passage 271 with a first communication opening 271a and a second communication passage 272 with a second communication opening 272a respectively in communication with the lower liquid chamber 24. The first and second communication openings 271a, 272a are the inlets of the working fluid. In addition, the communication passages 27 further include a third communication passage 273 with a third communication opening 273a in communication with the upper liquid chamber 22. The third communication opening 273a is the outlet of the working fluid. Reversely, alternatively, the first and second communication openings 271a, 272a are the outlets of the working fluid, while the third communication opening 273a is the inlet of the working fluid.

As shown in FIG. 2D, the working fluid carrying heat flows from the first and second communication openings 271a, 272a into the lower liquid chamber 24. After the lower liquid chamber 24 is filled up with the working fluid, the working fluid passes through the communication unit 253 to flow into the upper liquid chamber 22. The heat carried by the working fluid is conducted to the top plate 21 and the bottom plate 23 to dissipate the heat by way of radiation.

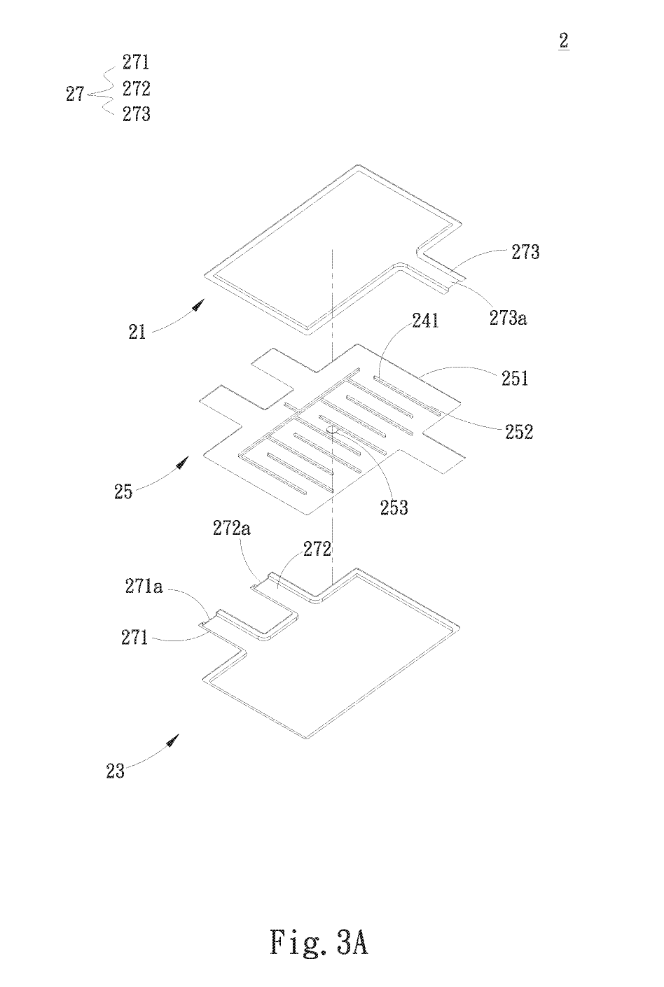

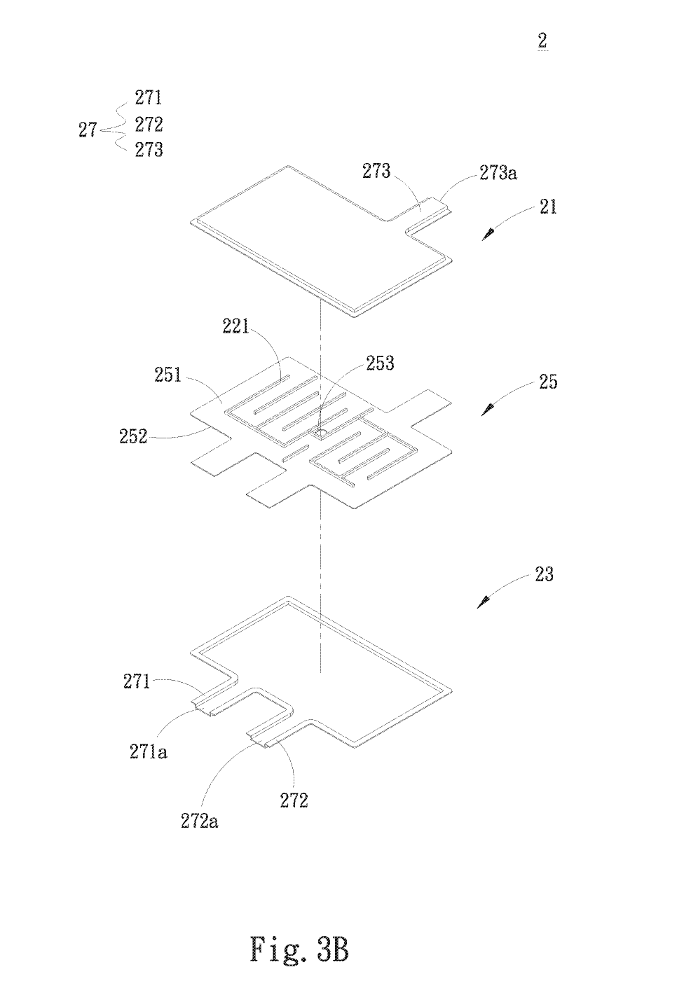

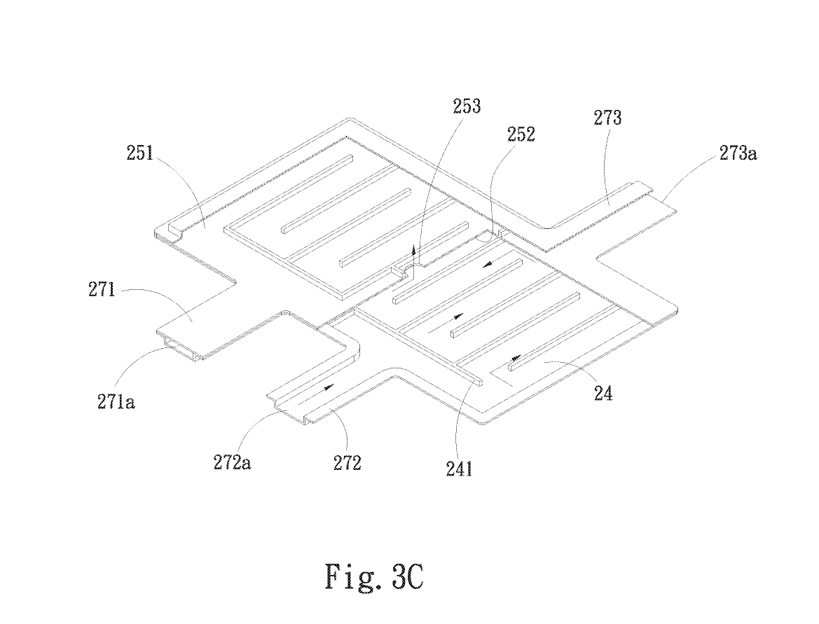

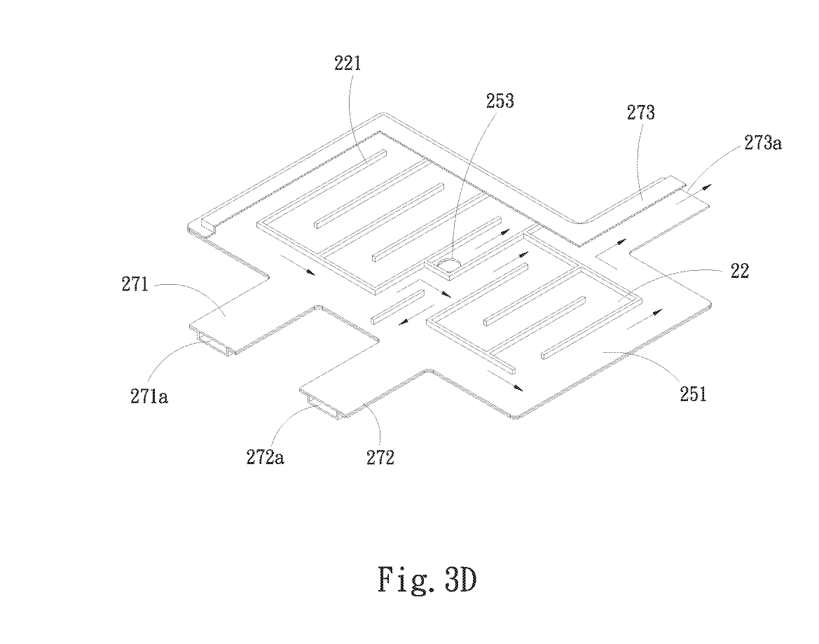

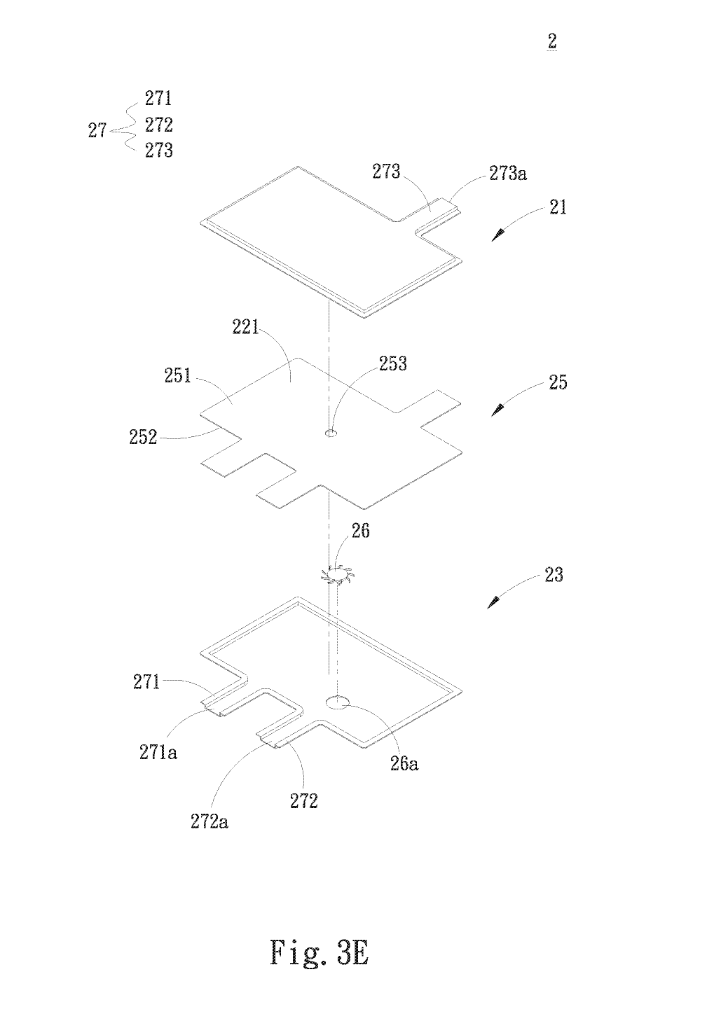

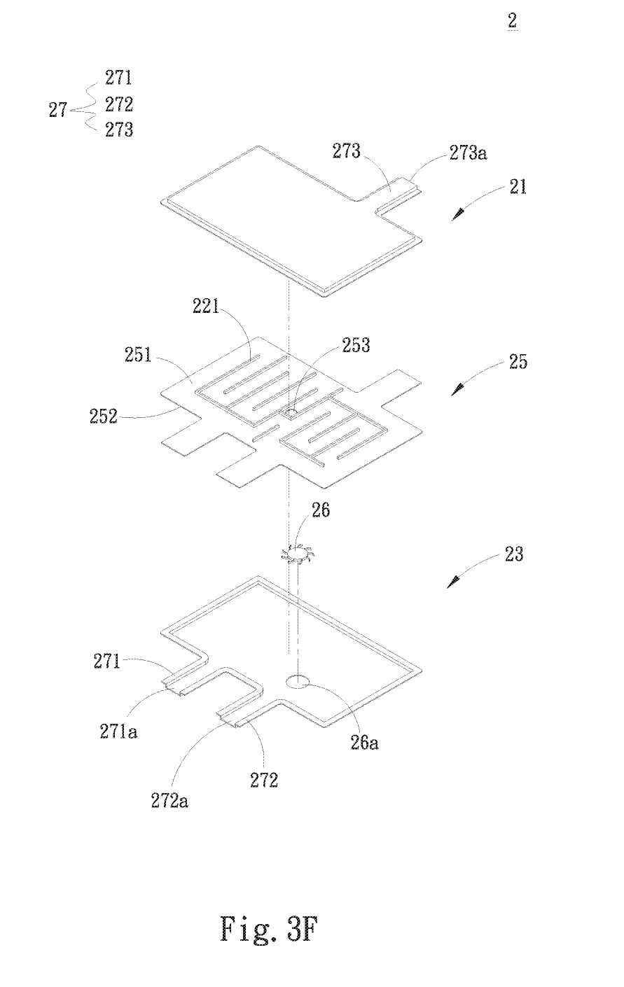

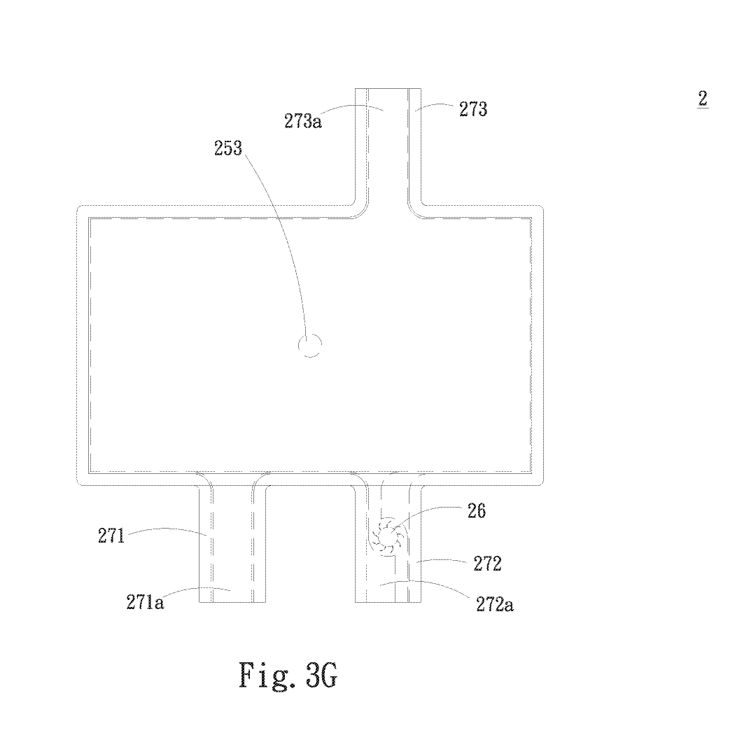

Referring to FIGS. 3A and 2B, in a modified embodiment, a lower flow way 241 is disposed in the lower liquid chamber 24. The lower flow way 241 is windingly formed on the lower face 252 of the substrate 25 proximal to the lower liquid chamber 24 as a flow path for guiding the working fluid. The working fluid is a liquid with high specific heat coefficient such as water or pure water. As shown in FIGS. 3B and 2A, in another modified embodiment, in addition to the lower flow way 241 disposed in the lower liquid chamber 24, an upper flow way 221 is also disposed in the upper liquid chamber 22. The upper flow way 221 is windingly formed on the upper face 251 of the substrate 25 proximal to the upper liquid chamber 22 as a flow path for guiding the working fluid. As shown in FIGS. 3C and 3D, by means of the upper and lower flow ways 221, 241, the flowing time of the working fluid within the upper and lower liquid chambers 22, 24 is prolonged so as to prolong the heat exchange time of the working fluid with the top plate 21 and the bottom plate 23. In this case, the heat carried by the working fluid can be fully conducted to the top plate 21 and the bottom plate 23 to dissipate the heat. In addition, as shown in FIGS. 3E and 3F, in another modified embodiment, a pump 26 is, but not limited to, disposed in a receiving sink 26a in the lower liquid chamber 24. In still another modified embodiment, the pump 26 can be alternatively disposed in the upper liquid chamber 22. As shown in FIG. 3G, in still another modified embodiment, the pump 26 is, but not limited to, disposed near the second communication opening 272a of the second communication passage 272. In still another modified embodiment, the pump 26 can be alternatively disposed at the first communication opening 271a of the first communication passage 271 or the third communication opening 273a of the third communication passage 273. The pump 26 of the present invention can be selectively disposed in any chamber or flow way. For example, the pump 26 includes a fan impeller and a drive motor (such as submersible motor or waterproof water) for driving the fan impeller to rotate so as to drive the working fluid to flow.

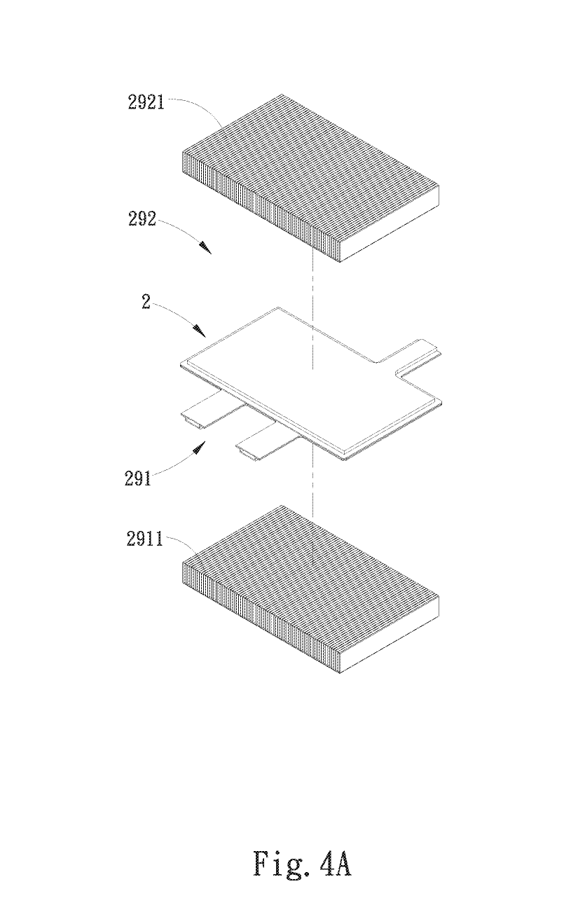

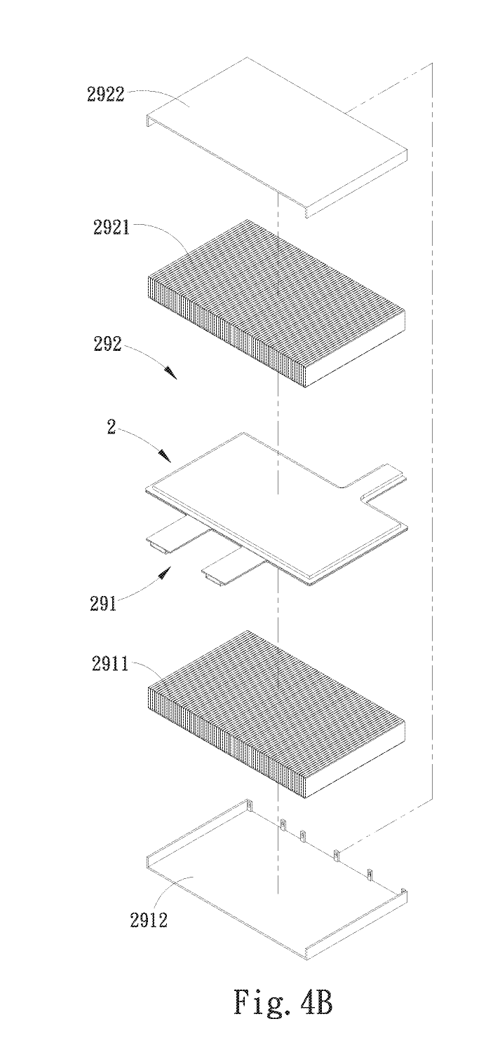

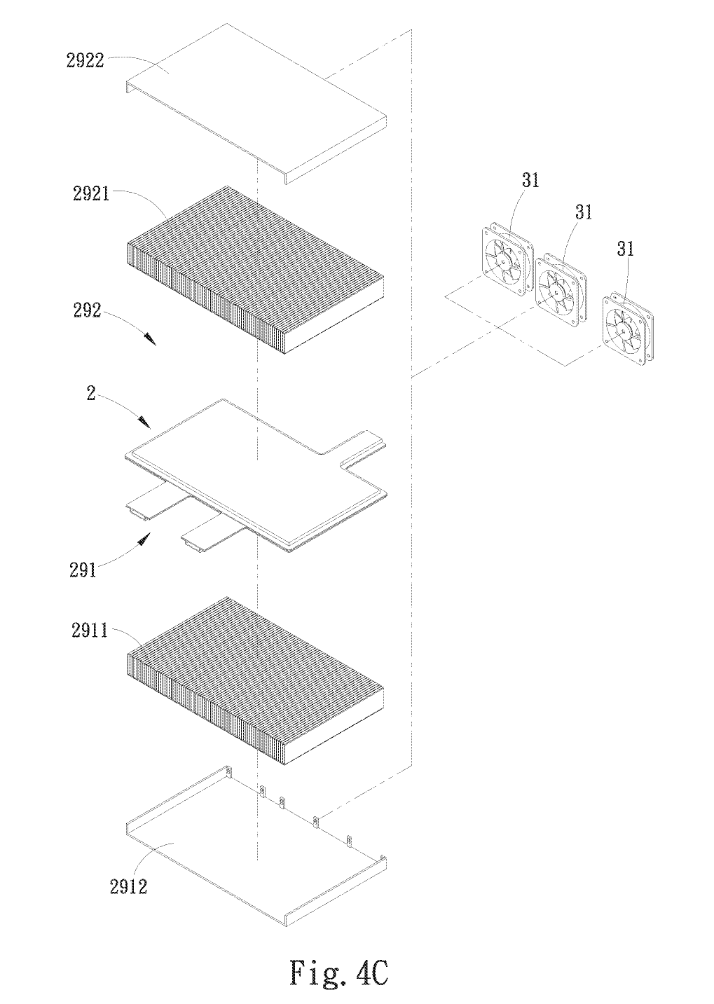

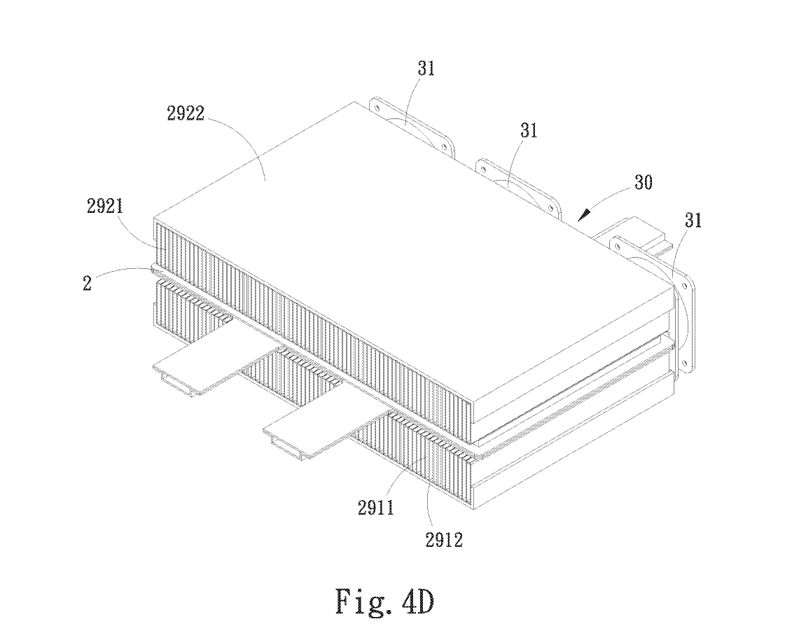

As shown in FIGS. 4A as well as 2A˜2C, in another modified embodiment, an open place is positioned on one face of the bottom plate 23 distal from the top plate 21 as a first heat dissipation space 291. An open place is positioned on one face of the top plate 21 distal from the bottom plate 23 as a second heat dissipation space 292. A first radiating fin assembly 2911 is disposed in the first heat dissipation space 291 on one face of the bottom plate 23 distal from the top plate 21. A second radiating fin assembly 2921 is disposed in the second heat dissipation space 292 on one face of the top plate 21 distal from the bottom plate 23. The first and second radiating fin assemblies 2911, 2921 are respectively formed of multiple radiating fins to enlarge the heat exchange area and enhance heat dissipation efficiency.

As shown in FIG. 4B, in another modified embodiment, the first radiating fin assembly 2921 disposed in the first heat dissipation space 291 is equipped with a first protection case 2912. The second radiating fin assembly 2921 disposed in the second heat dissipation space 292 is equipped with a second protection case 2922. The first and second protection cases 2912, 2922 serve to protect the first and second radiating fin assemblies 2911, 2921 from being deformed due to external collision to affect the heat dissipation efficiency as a whole. As shown in FIGS. 4C and 4D as well as FIG. 2C, in another modified embodiment, the top plate 21, the bottom plate 23, the substrate 25 and the first and second radiating fin assemblies 2911, 2921 together define a lateral side 30. At least one fan 31 is disposed on the lateral side 30. In this embodiment, there are three fans 31. Please refer to FIGS. 4A and 4B again. The heat carried by the working fluid is conducted to the top plate 21 and the bottom plate 23. Then, the heat passes through the first and second radiating fin assemblies 2911, 2921 to dissipate. The at least one fan 31 serves to enhance the heat dissipation effect of the first and second radiating fin assemblies 2911, 2921. In another modified embodiment, any of the communication passages 27 is mated with and in communication with a water-cooling module disposed outside the multi-outlet-inlet laminated liquid-cooling heat dissipation structure 2. The water-cooling module is in contact with a heat source (not shown). In this embodiment, the communication passages 27 are connected to the water-cooling module via multiple communication tubes, whereby the working fluid can absorb the heat of the heat source from the water-cooling module and then flow into the multi-outlet-inlet laminated liquid-cooling heat dissipation structure 2 to heat exchange and dissipate the heat.

In the first embodiment, the top plate 21, the bottom plate 23, the substrate 25 and the communication passages 27 are, but not limited to, made of titanium material. Alternatively, the top plate 21, the bottom plate 23, the substrate 25 and the communication passages 27 can be made of gold, silver, copper, iron, aluminum, aluminum alloy or copper alloy material.

By means of the design of the top plate 21, the bottom plate 23 mated with the top plate 21 and the substrate 25 sandwiched between the top plate 21 and the bottom plate 23, the top plate 21 and the bottom plate 23 themselves have larger heat absorption area on the inner sides for directly contacting and conducting the heat carried by the flowing working fluid. Also, the top plate 21 and the bottom plate 23 themselves have larger heat dissipation area on the outer sides for quickly outward dissipating the heat by way of radiation. Accordingly, the present invention has better heat dissipation performance and enlarged heat dissipation area. Furthermore, the upper and lower flow ways 221, 241 are disposed in the upper and lower liquid chambers 22, 24 to additionally increase (or prolong) the flowing time of the working fluid. This can effectively prolong the heat exchange time of the working fluid with the top plate 21 and the bottom plate 23. Moreover, the first and second radiating fin assemblies 2911, 2921 and the at least one fan 31 serve to enhance the heat dissipation effect. In addition, the first and second protection cases 2912, 2922 serve to protect the first and second radiating fin assemblies 2911, 2921 from being deformed when impacted.

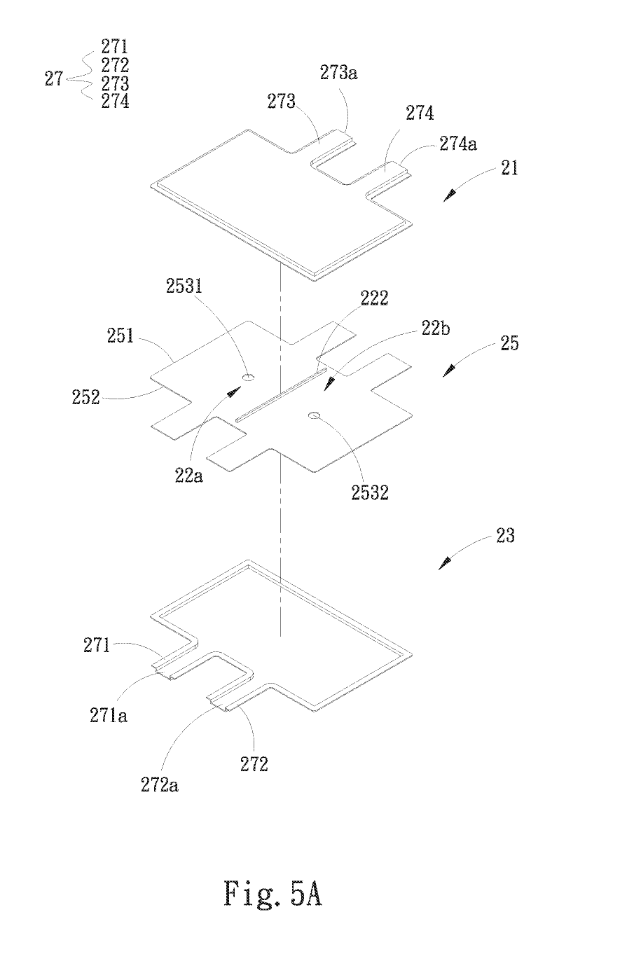

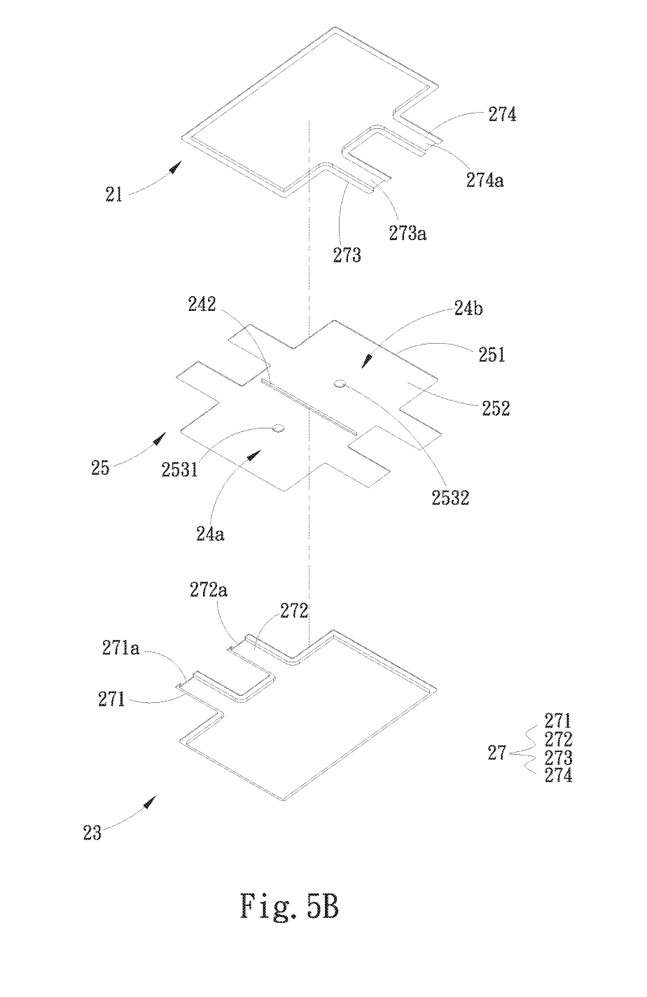

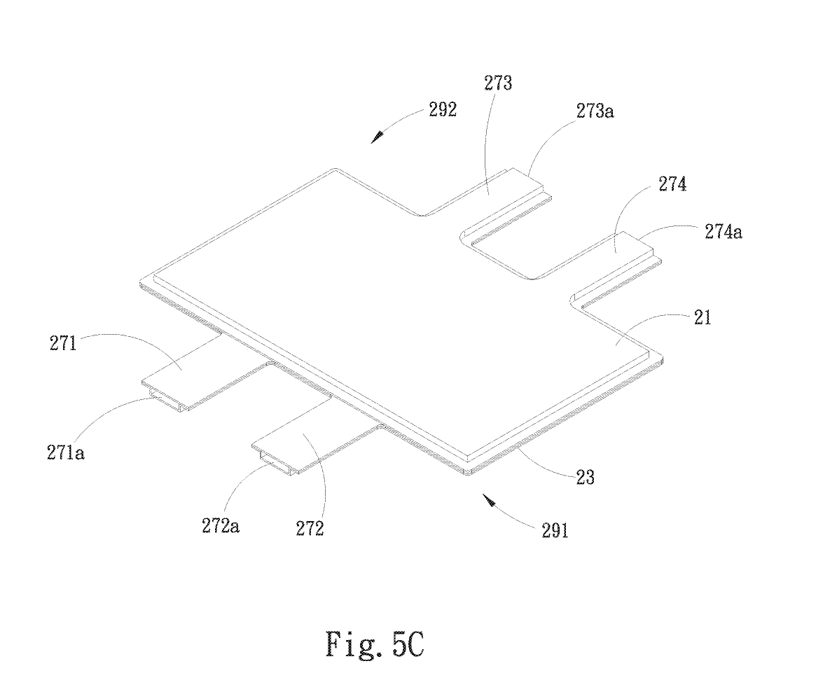

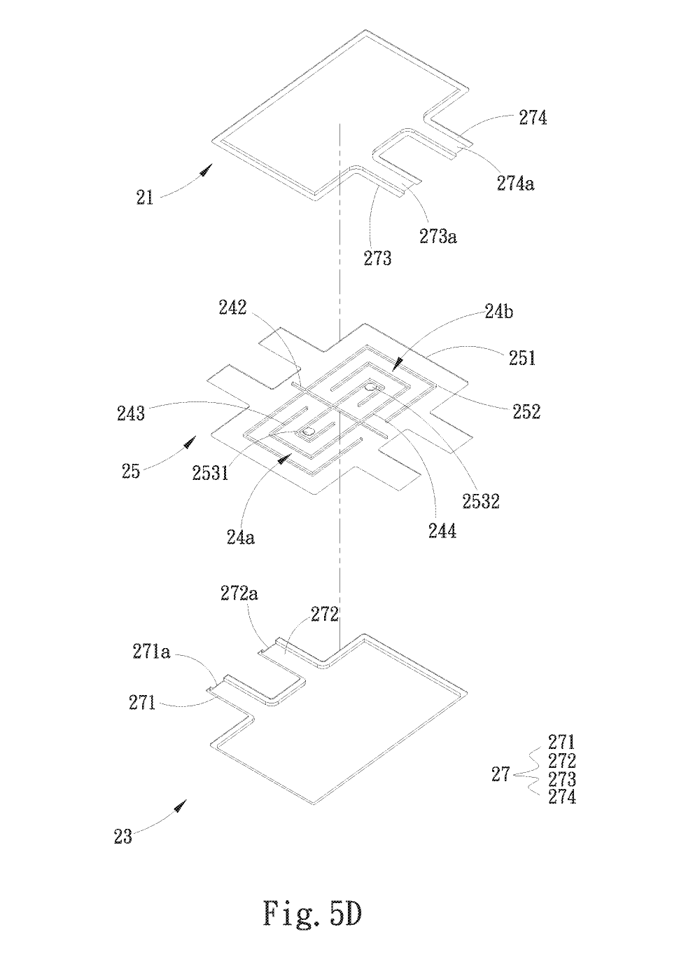

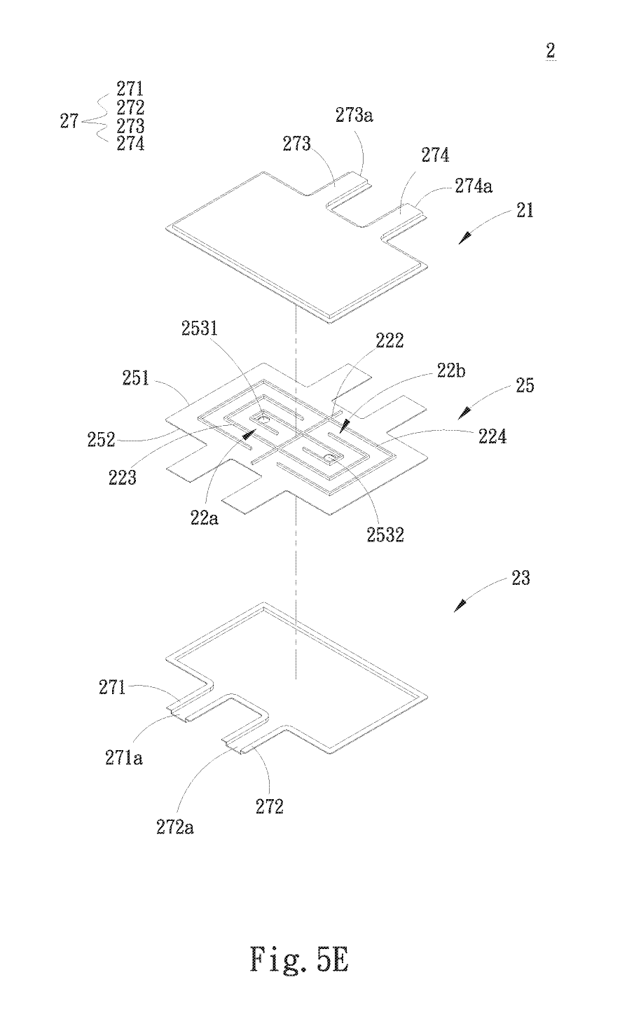

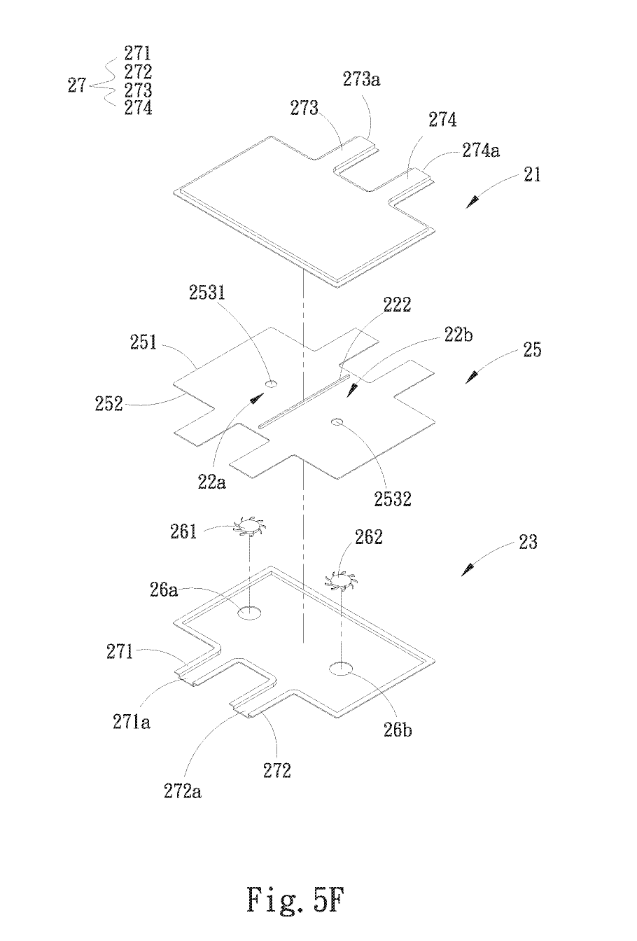

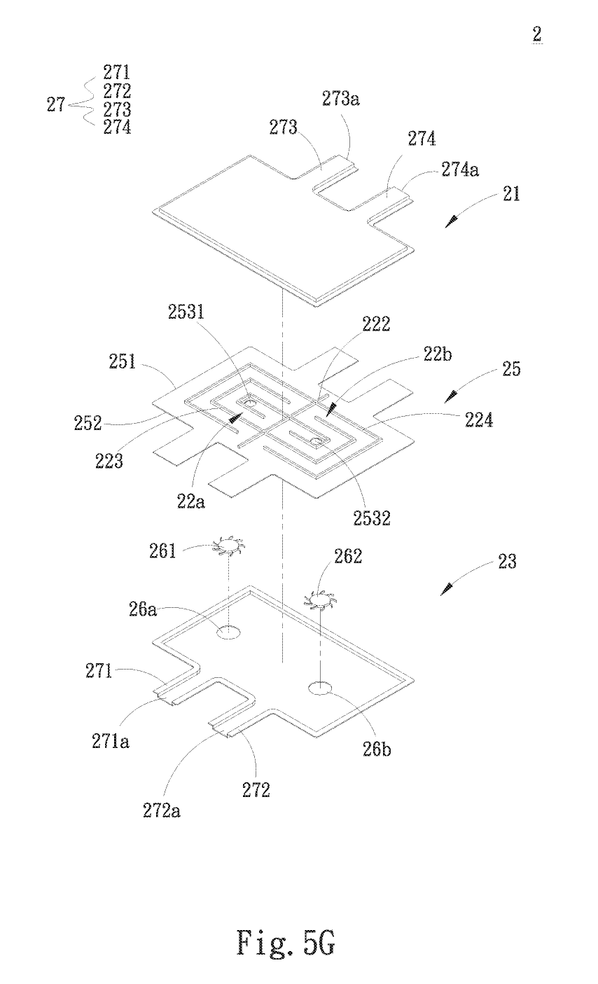

Please further refer to FIGS. 5A, 5B, 5C, 5D, 5E, 5F and 5G. FIG. 5A is a perspective exploded view of a second embodiment of the multi-outlet-inlet laminated liquid-cooling heat dissipation structure of the present invention. FIG. 5B is a perspective exploded view of the second embodiment of the multi-outlet-inlet laminated liquid-cooling heat dissipation structure of the present invention, seen from another angle. FIG. 5C is a perspective assembled view of the second embodiment of the multi-outlet-inlet laminated liquid-cooling heat dissipation structure of the present invention. FIG. 5D is a perspective exploded view of a modified embodiment of the second embodiment of the multi-outlet-inlet laminated liquid-cooling heat dissipation structure of the present invention. FIG. 5E is a perspective exploded view of another modified embodiment of the second embodiment of the multi-outlet-inlet laminated liquid-cooling heat dissipation structure of the present invention. FIG. 5F is a perspective exploded view of another modified embodiment of the second embodiment of the multi-outlet-inlet laminated liquid-cooling heat dissipation structure of the present invention. FIG. 5G is a perspective exploded view of another modified embodiment of the second embodiment of the multi-outlet-inlet laminated liquid-cooling heat dissipation structure of the present invention. As shown in FIGS. 5A and 5B as well as FIGS. 2A to 2D, the second embodiment is substantially identical to the first embodiment in structure, connection relationship and effect and thus will not be redundantly described hereinafter. The second embodiment is different from the first embodiment in that a first partitioning member 242 is disposed in the lower liquid chamber 24 to partition the lower liquid chamber 24 into a first liquid chamber 24a and a second liquid chamber 24b, which are independent from each other without interfering with each other. A second partitioning member 222 is disposed in the upper liquid chamber 22 to partition the upper liquid chamber 22 into a third liquid chamber 22a and a fourth liquid chamber 22b, which are independent from each other without interfering with each other. In this embodiment, the at least one communication unit 253 in communication with the upper and lower liquid chambers 22, 24 includes a first communication unit 2531 and a second communication unit 2532. The first communication unit 2531 communicates with the first and third liquid chambers 24a, 22a, while the second communication unit 2532 communicates with the second and fourth liquid chambers 24b, 22b. In this embodiment, the communication passages 27 include a first communication passage 271, a second communication passage 272, a third communication passage 273 and a fourth communication passage 274. A first communication opening 271a of the first communication passage 271 communicates with the first liquid chamber 24a. A second communication opening 272a of the second communication passage 272 communicates with the second liquid chamber 24b. A third communication opening 273a of the third communication passage 273 communicates with the third liquid chamber 22a. A fourth communication opening 274a of the fourth communication passage 274 communicates with the fourth liquid chamber 22b.

The working fluid flows through the first and second communication openings 271a, 272a of the first and second communication passages 271, 272 respectively into the first and second liquid chambers 24a, 24b. The first partitioning member 242 isolates the first and second liquid chambers 24a, 24b from each other so that the working fluid flowing into the first and second liquid chambers 24a, 24b respectively passes through the first and second communication units 2531, 2532 into the third and fourth liquid chambers 22a, 22b. Finally, the working fluid respectively flows from the third and fourth communication openings 273a, 274a of the third and fourth communication passages 273, 274 out of the third and fourth liquid chambers 22a, 22b. Accordingly, in this embodiment, the heat carried by the working fluid can be also conducted to the top plate 21 and the bottom plate 23 and dissipated by way of radiation.

As shown in FIGS. 5D and 5E, in a modified embodiment, a first flow way 243, a second flow way 244, a third flow way 223 and a fourth flow way 224 are respectively disposed in the first, second, third and fourth liquid chambers 24a, 24b, 22a, 22b. The first and second flow ways 243, 244 are windingly formed on the lower face of the substrate 25 proximal to the lower liquid chamber 24. The third and fourth flow ways 223, 224 are windingly formed on the upper face of the substrate 25 proximal to the upper liquid chamber 22 as a flow path for guiding the working fluid.

By means of the first, second, third and fourth flow ways 243, 244, 223, 224, the flowing time of the working fluid within the first, second, third and fourth liquid chambers 24a, 24b, 22a, 22b is prolonged so as to prolong the heat exchange time of the working fluid with the top plate 21 and the bottom plate 23.

As shown in FIGS. 5F and 5G, in another modified embodiment, a first pump 261 is, but not limited to, disposed in a receiving sink 26a in the first liquid chamber 24a (as shown in FIG. 5B). In still another modified embodiment, the first pump 261 can be alternatively disposed in the third liquid chamber 22a. In addition, a second pump 262 is, but not limited to, disposed in a receiving sink 26b in the second liquid chamber 24b (as shown in FIG. 5B). In still another modified embodiment, the second pump 262 can be alternatively disposed in the fourth liquid chamber 22a. The first and second pumps serve to drive the working fluid to flow.

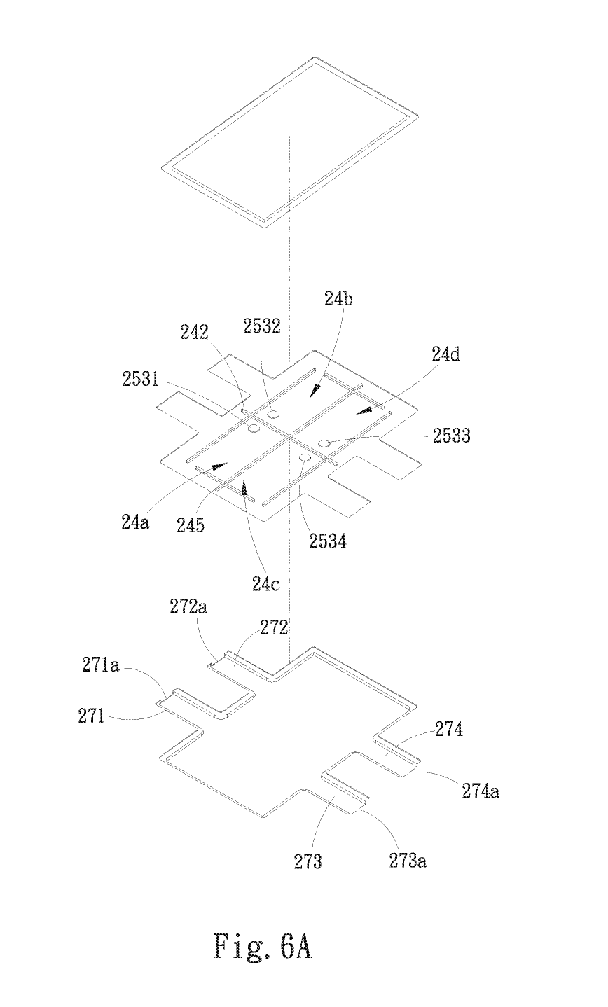

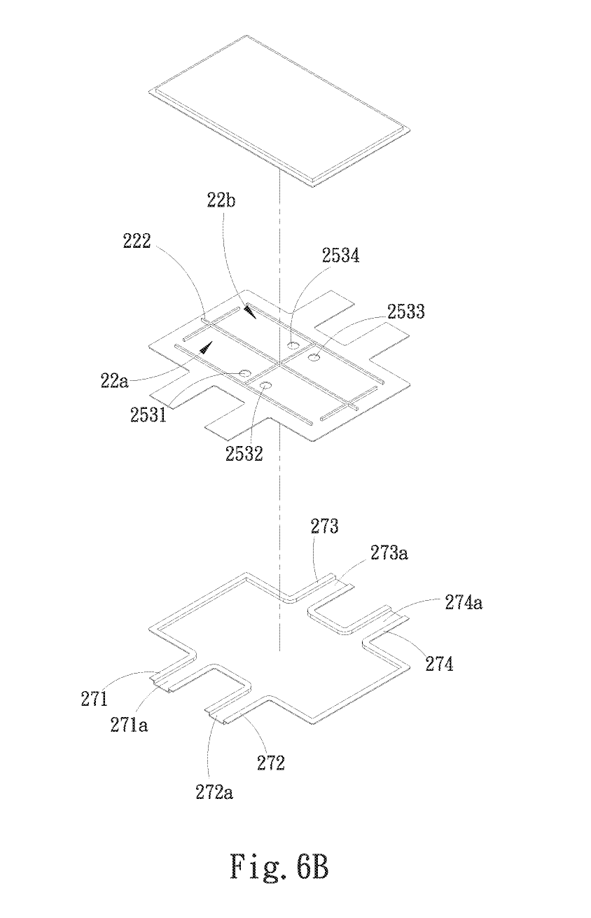

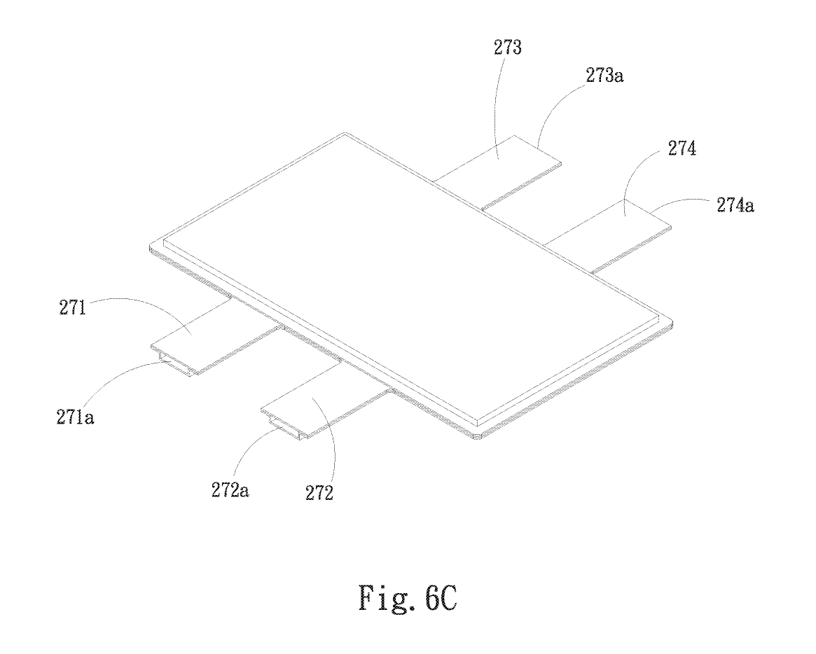

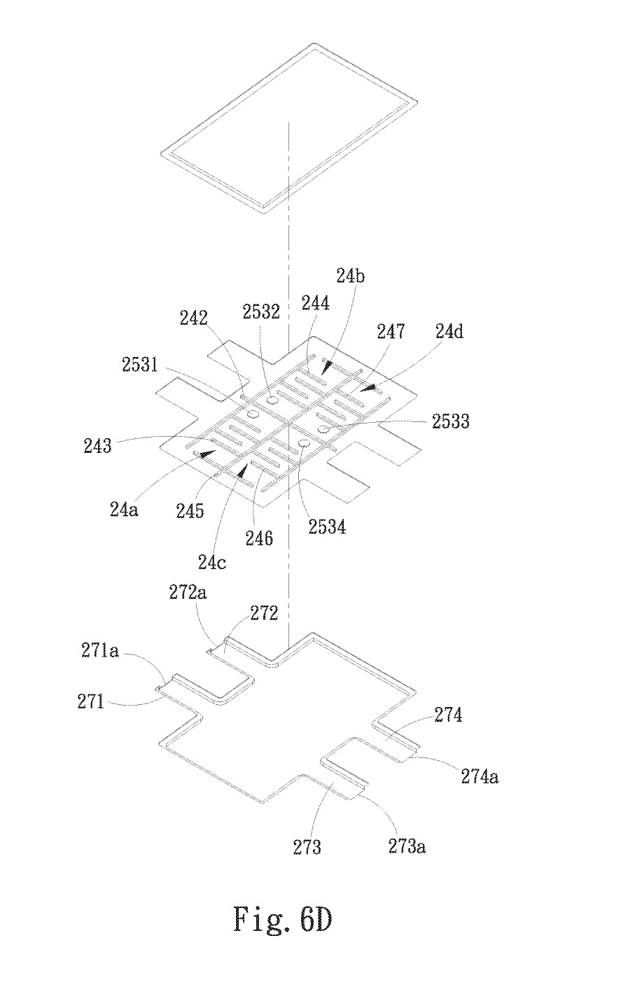

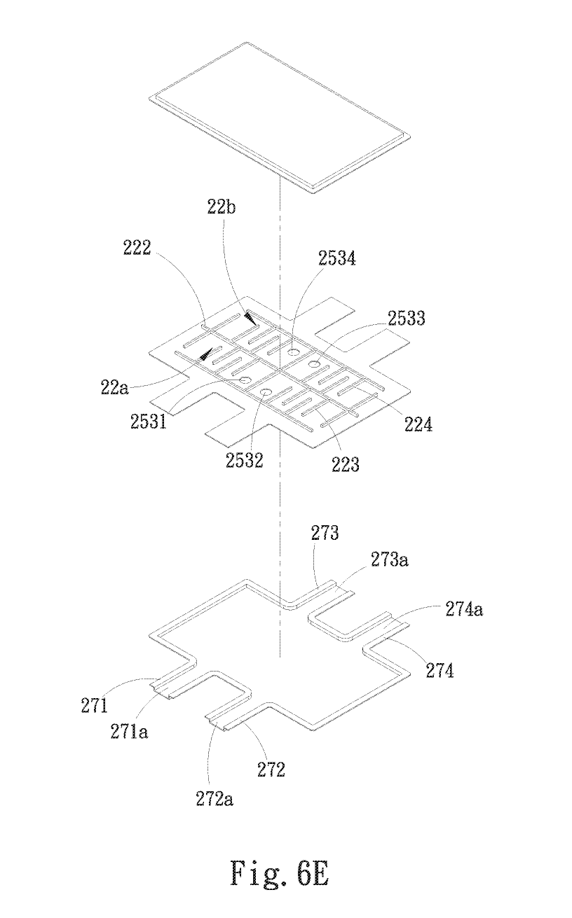

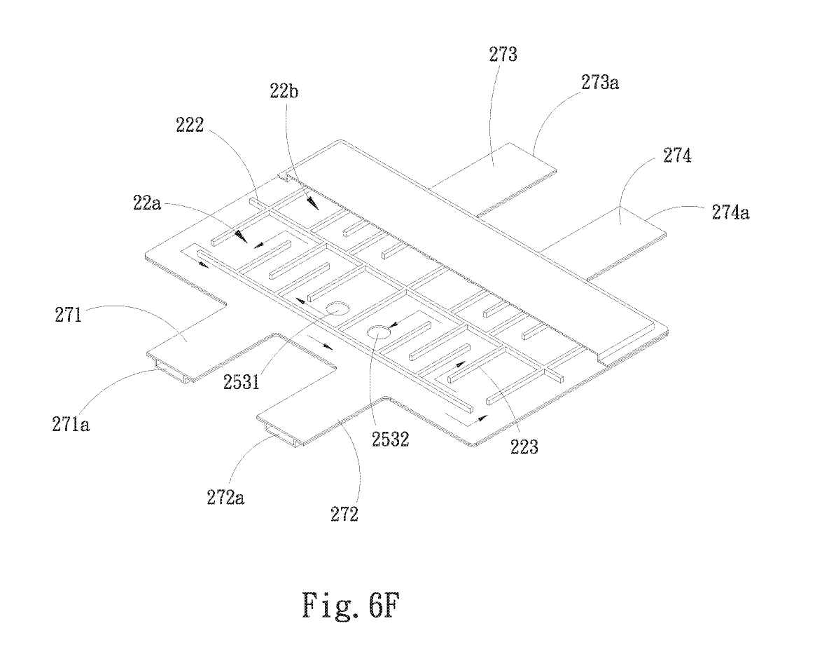

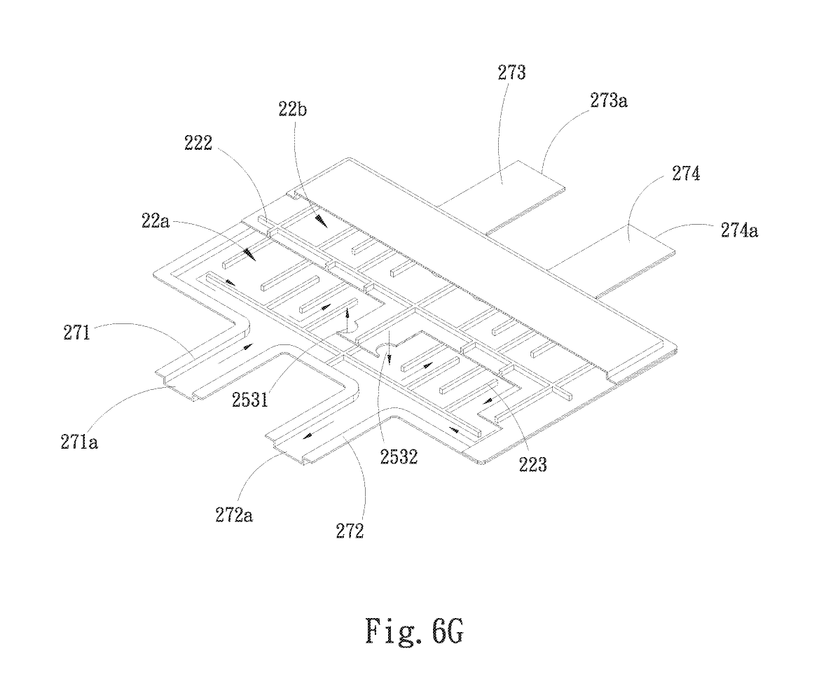

Please further refer to FIGS. 6A, 6B, 6C, 6D, 6E, 6F and 6G. FIG. 6A is a perspective exploded view of a third embodiment of the multi-outlet-inlet laminated liquid-cooling heat dissipation structure of the present invention. FIG. 6B is a perspective exploded view of the third embodiment of the multi-outlet-inlet laminated liquid-cooling heat dissipation structure of the present invention, seen from another angle. FIG. 6C is a perspective assembled view of the third embodiment of the multi-outlet-inlet laminated liquid-cooling heat dissipation structure of the present invention. FIG. 6D is a perspective exploded view of a modified embodiment of the third embodiment of the multi-outlet-inlet laminated liquid-cooling heat dissipation structure of the present invention. FIG. 6E is a perspective exploded view of another modified embodiment of the third embodiment of the multi-outlet-inlet laminated liquid-cooling heat dissipation structure of the present invention. FIG. 6F is a partially sectional view of another modified embodiment of the third embodiment of the multi-outlet-inlet laminated liquid-cooling heat dissipation structure of the present invention. FIG. 6G is a partially sectional view of another modified embodiment of the third embodiment of the multi-outlet-inlet laminated liquid-cooling heat dissipation structure of the present invention. As shown in FIGS. 6A and 6B as well as FIGS. 5A to 5G, the third embodiment is substantially identical to the second embodiment in structure, connection relationship and effect and thus will not be redundantly described hereinafter. The third embodiment is different from the second embodiment in that a third partitioning member 245 is further disposed in the lower liquid chamber 24 to partition the first and second liquid chambers 24a, 24b to respectively form a fifth liquid chamber 24c and a sixth liquid chamber 24d. In this embodiment, the at least one communication unit 253 in communication with the upper and lower liquid chambers 22, 24 further includes a third communication unit 2533 and a fourth communication unit 2534. The first communication unit 2531 communicates with the first and third liquid chambers 24a, 22a, the second communication unit 2532 communicates with the second and third liquid chambers 24b, 22a, the third communication unit 2533 communicates with the fifth and fourth liquid chambers 24c, 22b, while the fourth communication unit 2534 communicates with the sixth and fourth liquid chambers 24d, 22b.

In this embodiment, the first communication opening 271a of the first communication passage 271 communicates with the first liquid chamber 24a. The first communication opening 271a is the inlet of the working fluid. The second communication opening 272a of the second communication passage 272 communicates with the second liquid chamber 24b. The second communication opening 272a is the outlet of the working fluid. The third communication opening 273a of the third communication passage 273 communicates with the fifth liquid chamber 24c. The third communication opening 273a is the inlet of the working fluid. The fourth communication opening 274a of the fourth communication passage 274 communicates with the sixth liquid chamber 24d. The fourth communication opening 273a is the inlet of the working fluid.

The working fluid flows through the first communication opening 271a of the first communication passage 271 into the first liquid chamber 22a. The first partitioning member 242 isolates the first and second liquid chambers 24a, 24b from each other so that the working fluid flowing into the first liquid chamber 24a passes through the first communication unit 2531 into the third liquid chamber 22a and the working fluid flowing into the third liquid chamber 22a thereafter passes through the second communication unit 2532 into the second liquid chamber 24b and flows out from the second communication opening 272a of the second communication passage 272. At the same time, another working fluid flows through the third communication opening 273a of the third communication passage 273 into the fifth liquid chamber 24c. The first partitioning member 242 isolates the fifth and sixth liquid chambers 24c, 24d from each other so that the working fluid flowing into the fifth liquid chamber 24c passes through the third communication unit 2533 into the fourth liquid chamber 22b and the working fluid flowing into the fourth liquid chamber 22b thereafter passes through the fourth communication unit 2534 into the sixth liquid chamber 24d and flows out from the fourth communication opening 274a of the fourth communication passage 274. Accordingly, in this embodiment, the heat carried by the working fluid can be also conducted to the top plate 21 and the bottom plate 23 and dissipated by way of radiation.

As shown in FIGS. 6D and 6E, in a modified embodiment, a first flow way 243, a second flow way 244, a third flow way 223, a fourth flow way 224, a fifth flow way 246 and a sixth flow way 247 are respectively disposed in the first, second, third, fourth, fifth and sixth liquid chambers 24a, 24b, 22a, 22b, 24c, 24d. The first, second, fifth and sixth flow ways 243, 244, 246, 247 are windingly formed on the lower side of the substrate 25 proximal to the lower liquid chamber 24. The third and fourth flow ways 223, 224 are windingly formed on the upper face of the substrate 25 proximal to the upper liquid chamber 22 as a flow path for guiding the working fluid.

As shown in FIGS. 6F and 6G, by means of the first, second, third, fourth, fifth and sixth flow ways 243, 244, 223, 224, 246, 247 (as shown in FIGS. 6D and 6E), the flowing time of the working fluid within the first, second, third, fourth, fifth and sixth liquid chambers 24a, 24b, 22a, 22b, 24c, 24d (as shown in FIGS. 6D and 6E) is prolonged so as to prolong the heat exchange time of the working fluid with the top plate 21 and the bottom plate 23.

As in the second embodiment, the first pump 261 can be disposed in a receiving sink in any of the first, second and third liquid chambers 24a, 24b, 22a, while the second pump 262 can be disposed in another receiving sink in any of the fourth, fifth and sixth liquid chambers 22b, 24c, 24d to drive the working fluid to flow.

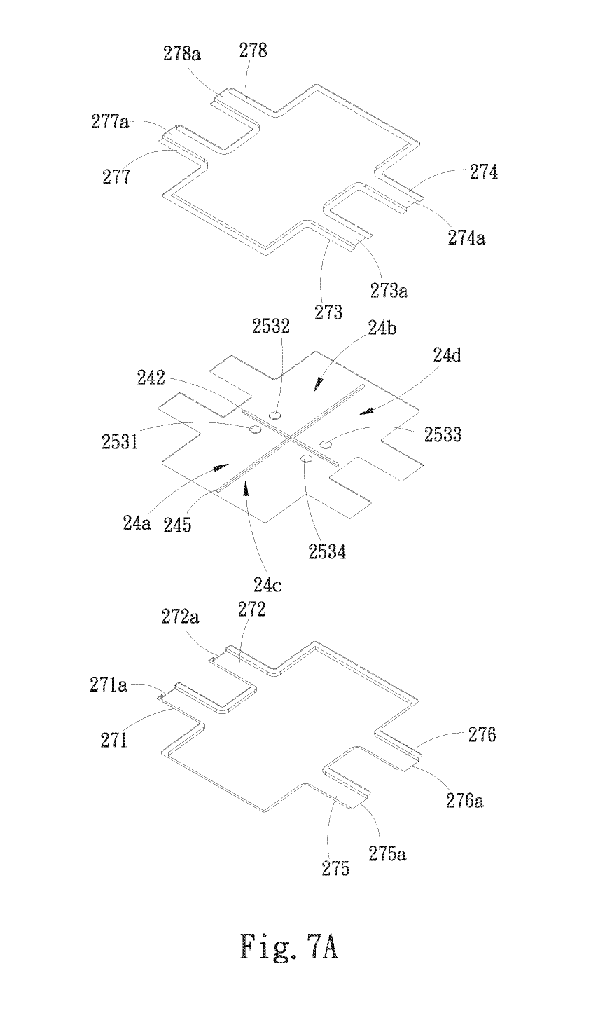

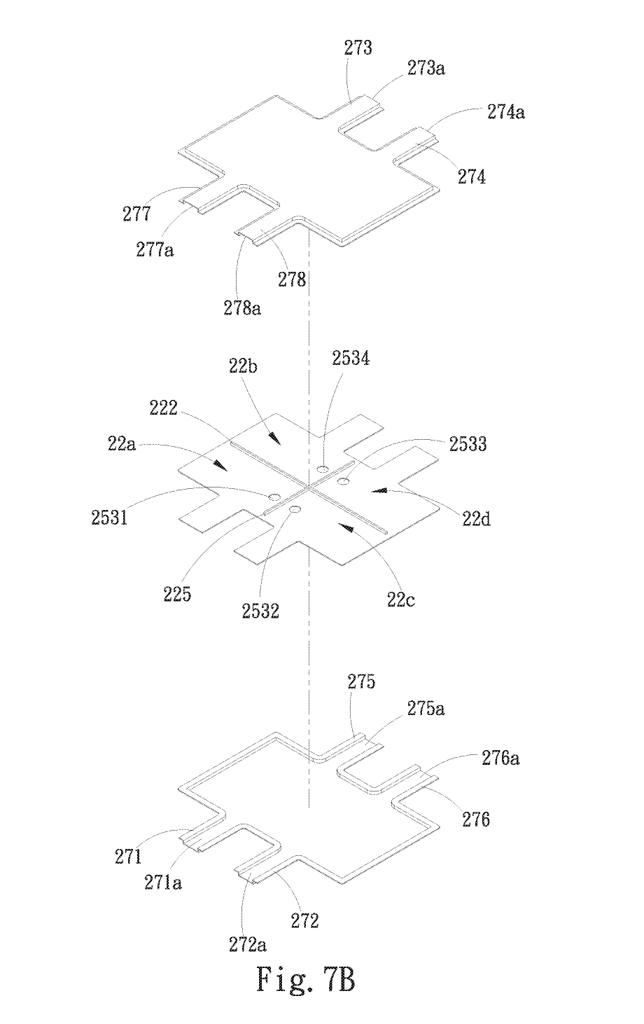

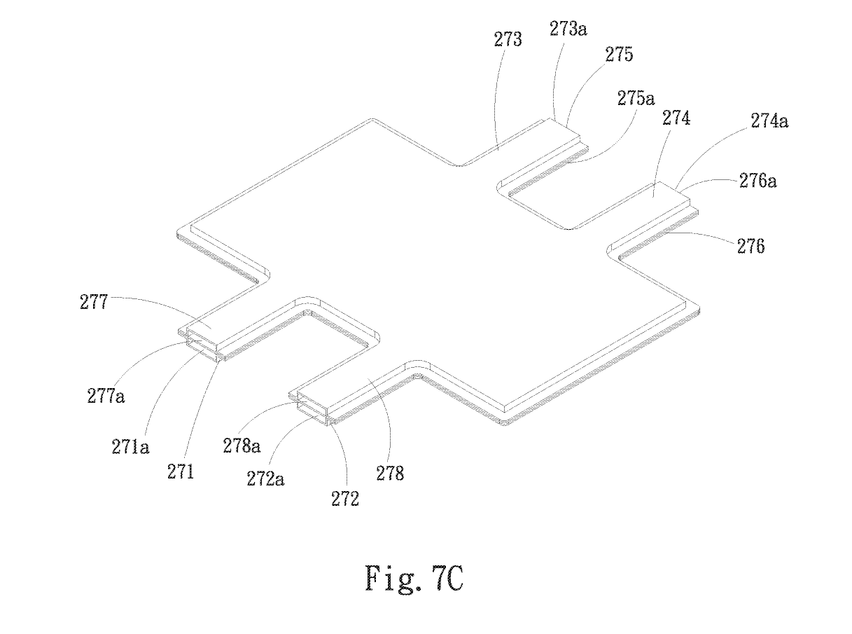

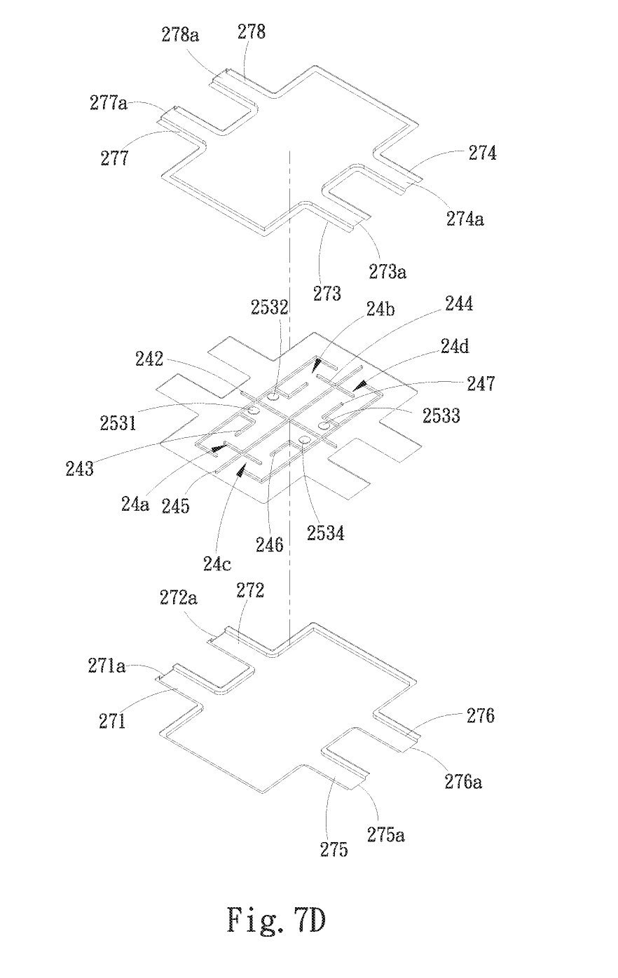

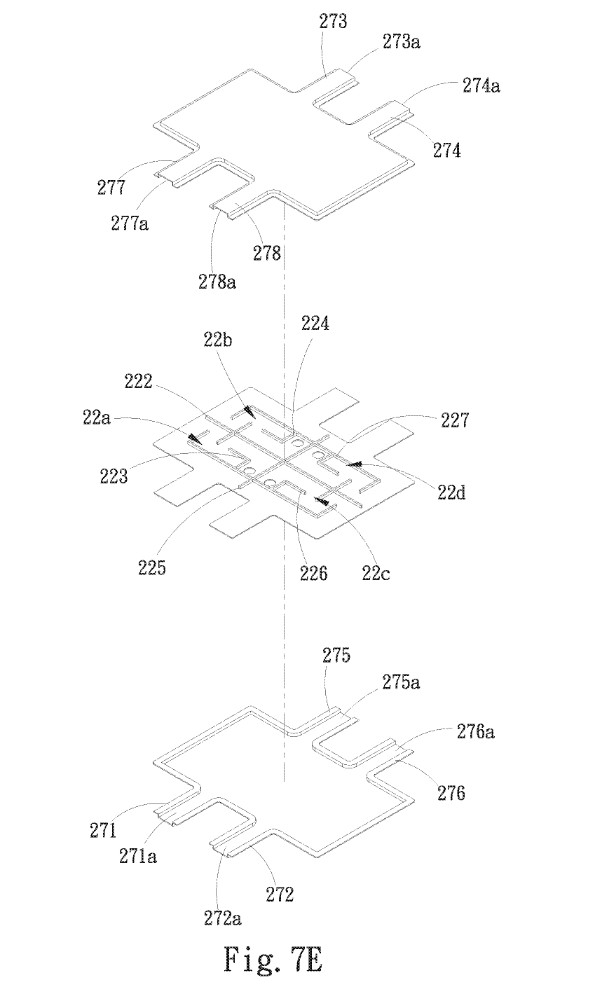

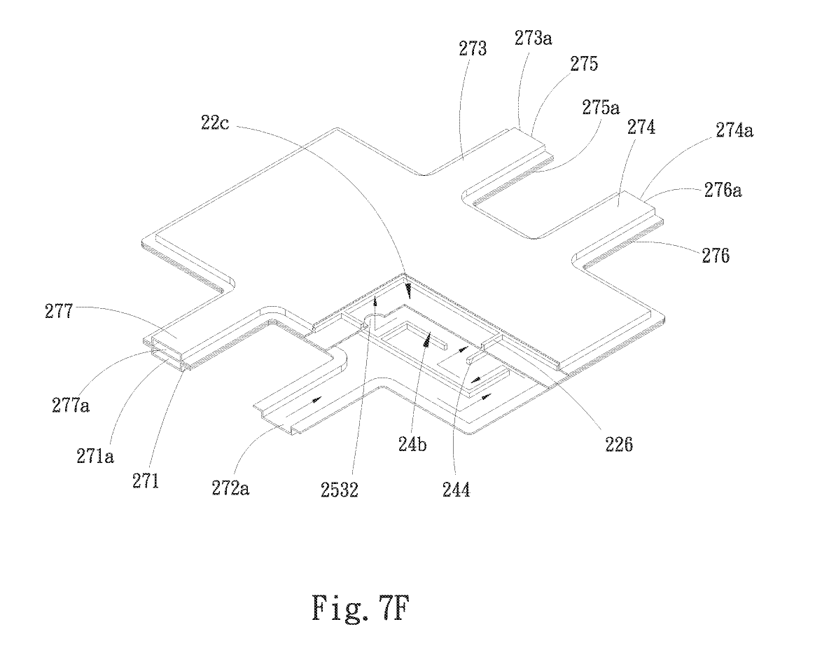

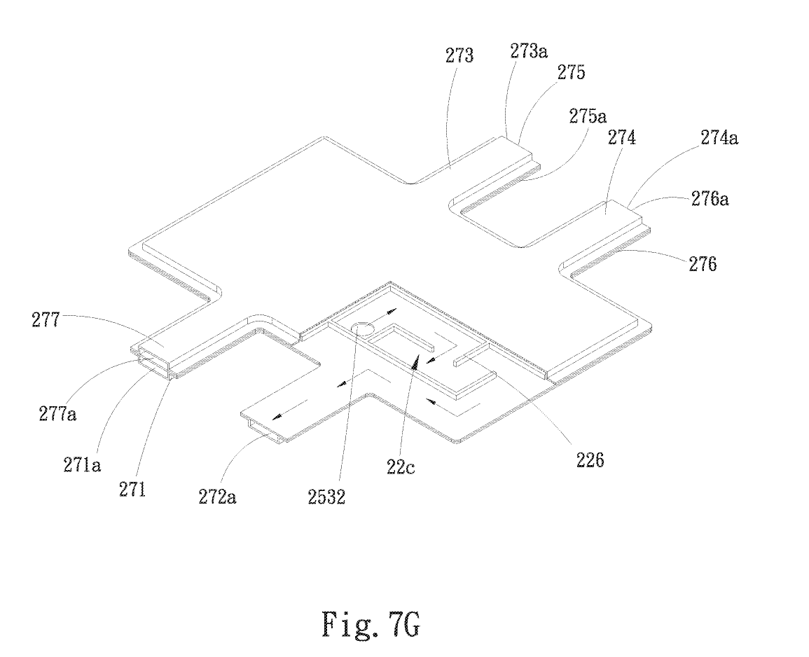

Please now refer to FIGS. 7A, 7B, 7C, 7D, 7E, 7F, 7G. FIG. 7A is a perspective exploded view of a fourth embodiment of the multi-outlet-inlet laminated liquid-cooling heat dissipation structure of the present invention. FIG. 7B is a perspective exploded view of the fourth embodiment of the multi-outlet-inlet laminated liquid-cooling heat dissipation structure of the present invention, seen from another angle. FIG. 7C is a perspective assembled view of the fourth embodiment of the multi-outlet-inlet laminated liquid-cooling heat dissipation structure of the present invention. FIG. 7D is a perspective exploded view of a modified embodiment of the fourth embodiment of the multi-outlet-inlet laminated liquid-cooling heat dissipation structure of the present invention. FIG. 7E is a perspective exploded view of another modified embodiment of the fourth embodiment of the multi-outlet-inlet laminated liquid-cooling heat dissipation structure of the present invention. FIG. 7F is a partially sectional view of another modified embodiment of the fourth embodiment of the multi-outlet-inlet laminated liquid-cooling heat dissipation structure of the present invention. FIG. 7G is a partially sectional view of another modified embodiment of the fourth embodiment of the multi-outlet-inlet laminated liquid-cooling heat dissipation structure of the present invention. As shown in FIGS. 7A and 7B as well as FIGS. 6A to 6E, the fourth embodiment is substantially identical to the third embodiment in structure, connection relationship and effect and thus will not be redundantly described hereinafter. The fourth embodiment is different from the third embodiment in that a fourth partitioning member 225 is further disposed in the upper liquid chamber 22 to partition the third and fourth liquid chambers 22a, 22b to respectively form a seventh liquid chamber 22c and an eighth liquid chamber 22d. The at least one communication unit 253 includes a first communication unit 2531, a second communication unit 2532, a third communication unit 2533 and a fourth communication unit 2534. The first communication unit 2531 communicates with the first and third liquid chambers 24a, 22a. The second communication unit 2532 communicates with the second and seventh liquid chambers 24b, 22c. The third communication unit 2533 communicates with the sixth and eighth liquid chambers 24d, 22d. The fourth communication unit 2534 communicates with the fifth and fourth liquid chambers 24c, 22b.

In this embodiment, the first communication opening 271a of the first communication passage 271 communicates with the first liquid chamber 24a. The first communication opening 271a is the inlet of the working fluid. The second communication opening 272a of the second communication passage 272 communicates with the second liquid chamber 24b. The second communication opening 272a is the inlet of the working fluid. The third communication opening 273a of the third communication passage 273 communicates with the fourth liquid chamber 22b. The third communication opening 273a is the outlet of the working fluid. The fourth communication opening 274a of the fourth communication passage 274 communicates with the eighth liquid chamber 22d. The fourth communication opening 274a is the outlet of the working fluid.

The fifth communication opening 275a of the fifth communication passage 275 communicates with the fifth liquid chamber 24c. The fifth communication opening 275a is the inlet of the working fluid. The sixth communication opening 276a of the sixth communication passage 276 communicates with the sixth liquid chamber 24d. The sixth communication opening 276a is the inlet of the working fluid. The seventh communication opening 277a of the seventh communication passage 277 communicates with the third liquid chamber 22a. The seventh communication opening 277a is the outlet of the working fluid. The eighth communication opening 278a of the eighth communication passage 278 communicates with the seventh liquid chamber 22c. The eighth communication opening 278a is the outlet of the working fluid.

The working fluid flows through the first communication openings 271a of the first communication passage 271 into the first liquid chamber 24a. The working fluid flowing into the first liquid chamber 24a passes through the first communication unit 2531 into the third liquid chamber 22a. The working fluid flowing into the third liquid chamber 22a thereafter flows out from the seventh communication opening 277a of the third communication passage 277. At the same time, the other working fluid flows through the second communication openings 272a of the second communication passage 272 into the second liquid chamber 24b. The working fluid flowing into the second liquid chamber 24b passes through the second communication unit 2532 into the seventh liquid chamber 22c. The working fluid flowing into the seventh liquid chamber 22c thereafter flows out from the eighth communication opening 278a of the eighth communication passage 278.

In addition, the other working fluid flows through the fifth communication openings 275a of the fifth communication passage 275 into the fifth liquid chamber 24c. The working fluid flowing into the fifth liquid chamber 24c passes through the fourth communication unit 2534 into the fourth liquid chamber 22b. The working fluid flowing into the fourth liquid chamber 22b thereafter flows out from the third communication opening 273a of the eighth communication passage 273. At the same time, the other working fluid flows through the sixth communication openings 276a of the sixth communication passage 276 into the sixth liquid chamber 24d. The working fluid flowing into the sixth liquid chamber 24d passes through the third communication unit 2533 into the eighth liquid chamber 22d. The working fluid flowing into the eighth liquid chamber 22d thereafter flows out from the fourth communication opening 274a of the fourth communication passage 274. Accordingly, in this embodiment, the heat carried by the working fluid can be also conducted to the top plate 21 and the bottom plate 23 and dissipated by way of radiation.

As shown in FIGS. 7D and 7E, in a modified embodiment, a first flow way 243, a second flow way 244, a third flow way 223, a fourth flow way 224, a fifth flow way 246, a sixth flow way 247, a seventh flow way 226 and an eighth flow way 227 are respectively disposed in the first, second, third, fourth, fifth, sixth, seventh and eighth liquid chambers 24a, 24b, 22a, 22b, 24c, 24d, 22c, 22d. The first, second, fifth and sixth flow ways 243, 244, 246, 247 are windingly formed on the lower face of the substrate 25 proximal to the lower liquid chamber 24. The third, fourth, seventh and eighth flow ways 223, 224, 226, 227 are windingly formed on the upper face of the substrate 25 proximal to the upper liquid chamber 22 as a flow path for guiding the working fluid.

As shown in FIGS. 7F and 7G, by means of the first, second, third, fourth, fifth, sixth, seventh and eighth flow ways 243, 244, 223, 224, 246, 247, 226, 227 (as shown in FIGS. 7D and 7E), the flowing time of the working fluid within the first, second, third, fourth, fifth, sixth, seventh and eighth liquid chambers 24a, 24b, 22a, 22b, 24c, 24d, 22c, 22d is prolonged (as shown in FIGS. 7D and 7E) so as to prolong the heat exchange time of the working fluid with the top plate 21 and the bottom plate 23.

In a modified embodiment, the present invention further includes a third pump (not shown) and a fourth pump (not shown). The first pump 261 can be disposed in a receiving sink in any of the first and third liquid chambers 24a, 22a. The second pump 262 can be disposed in any of the second and seventh liquid chambers 24b, 22c. The third pump can be disposed in any of the fifth and fourth liquid chambers 24c, 22b. The fourth pump can be disposed in any of the sixth and eighth liquid chambers 24d, 22d to drive the working fluid to flow.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. A multi-outlet-inlet laminated liquid-cooling heat dissipation structure comprising:
a top plate;
a bottom plate mated with the top plate;
a substrate disposed between the top plate and the bottom plate, the substrate having an upper face, a lower face and at least one communication unit, the top plate and the upper face together defining an upper liquid chamber, the bottom plate and the lower face together defining a lower liquid chamber, the at least one communication unit passing through the substrate between the upper and lower faces to communicate with the upper and lower liquid chambers for a working fluid to flow through; and
multiple communication passages, each communication passage having a communication opening in communication with the upper and lower liquid chambers as an inlet or an outlet of the working fluid.

2. The multi-outlet-inlet laminated liquid-cooling heat dissipation structure as claimed in claim 1, wherein a lower flow way is disposed in the lower liquid chamber, the lower flow way being windingly formed on the lower face of the substrate proximal to the lower liquid chamber as a flow path for guiding the working fluid, an upper flow way being disposed in the upper liquid chamber, the upper flow way being windingly formed on the upper face of the substrate proximal to the upper liquid chamber as a flow path for guiding the working fluid.

3. The multi-outlet-inlet laminated liquid-cooling heat dissipation structure as claimed in claim 1, wherein the communication passages include a first communication passage with a first communication opening and a second communication passage with a second communication opening respectively in communication with the lower liquid chamber, the communication passages further including a third communication passage with a third communication opening in communication with the upper liquid chamber.

4. The multi-outlet-inlet laminated liquid-cooling heat dissipation structure as claimed in claim 1, further comprising a pump disposed in any of the upper liquid chamber, the lower liquid chamber and the communication passages.

5. The multi-outlet-inlet laminated liquid-cooling heat dissipation structure as claimed in claim 3, further comprising a pump disposed in any of the upper liquid chamber, the lower liquid chamber and the communication passages.

6. The multi-outlet-inlet laminated liquid-cooling heat dissipation structure as claimed in claim 1, wherein a first partitioning member is disposed in the lower liquid chamber to partition the lower liquid chamber into a first liquid chamber and a second liquid chamber, a second partitioning member being disposed in the upper liquid chamber to partition the upper liquid chamber into a third liquid chamber and a fourth liquid chamber.

7. The multi-outlet-inlet laminated liquid-cooling heat dissipation structure as claimed in claim 6, wherein the at least one communication unit includes a first communication unit and a second communication unit, the first communication unit communicating with the first and third liquid chambers, while the second communication unit communicating with the second and fourth liquid chambers.

8. The multi-outlet-inlet laminated liquid-cooling heat dissipation structure as claimed in claim 7, wherein the communication passages include a first communication passage, a second communication passage, a third communication passage and a fourth communication passage, a first communication opening of the first communication passage communicating with the first liquid chamber, a second communication opening of the second communication passage communicating with the second liquid chamber, a third communication opening of the third communication passage communicating with the third liquid chamber, a fourth communication opening of the fourth communication passage communicating with the fourth liquid chamber.

9. The multi-outlet-inlet laminated liquid-cooling heat dissipation structure as claimed in claim 7, wherein a first flow way, a second flow way, a third flow way and a fourth flow way are respectively disposed in the first, second, third and fourth liquid chambers, the first and second flow ways being windingly formed on the lower face of the substrate proximal to the lower liquid chamber, the third and fourth flow ways being windingly formed on the upper face of the substrate proximal to the upper liquid chamber as a flow path for guiding the working fluid.

10. The multi-outlet-inlet laminated liquid-cooling heat dissipation structure as claimed in claim 7, further comprising a first pump disposed in any of the first and third liquid chambers and a second pump disposed in any of the second and fourth liquid chambers.

11. The multi-outlet-inlet laminated liquid-cooling heat dissipation structure as claimed in claim 6, wherein a third partitioning member is further disposed in the lower liquid chamber to partition the first and second liquid chambers to respectively form a fifth liquid chamber and a sixth liquid chamber.

12. The multi-outlet-inlet laminated liquid-cooling heat dissipation structure as claimed in claim 11, wherein the at least one communication unit includes a first communication unit, a second communication unit, a third communication unit and a fourth communication unit, the first communication unit communicating with the first and third liquid chambers, the second communication unit communicating with the second and third liquid chambers, the third communication unit communicating with the fifth and fourth liquid chambers, while the fourth communication unit communicating with the sixth and fourth liquid chambers.

13. The multi-outlet-inlet laminated liquid-cooling heat dissipation structure as claimed in claim 12, wherein the communication passages include a first communication passage, a second communication passage, a third communication passage and a fourth communication passage, the first communication passage communicating with the first liquid chamber, the second communication passage communicating with the second liquid chamber, the third communication passage communicating with the fifth liquid chamber, while the fourth communication passage communicating with the sixth liquid chamber.

14. The multi-outlet-inlet laminated liquid-cooling heat dissipation structure as claimed in claim 12, wherein a first flow way, a second flow way, a third flow way, a fourth flow way, a fifth flow way and a sixth flow way are respectively disposed in the first, second, third, fourth, fifth and sixth liquid chambers, the first, second, fifth and sixth flow ways being windingly formed on the lower face of the substrate proximal to the lower liquid chamber, the third and fourth flow ways being windingly formed on the upper face of the substrate proximal to the upper liquid chamber as a flow path for guiding the working fluid.

15. The multi-outlet-inlet laminated liquid-cooling heat dissipation structure as claimed in claim 12, further comprising a first pump disposed in any of the first, second and third liquid chambers and a second pump disposed in any of the fourth, fifth and sixth liquid chambers.

16. The multi-outlet-inlet laminated liquid-cooling heat dissipation structure as claimed in claim 11, wherein a fourth partitioning member is further disposed in the upper liquid chamber to partition the third and fourth liquid chambers to respectively form a seventh liquid chamber and an eighth liquid chamber.

17. The multi-outlet-inlet laminated liquid-cooling heat dissipation structure as claimed in claim 16, wherein the at least one communication unit includes a first communication unit, a second communication unit, a third communication unit and a fourth communication unit, the first communication unit communicating with the first and third liquid chambers, the second communication unit communicating with the second and seventh liquid chambers, the third communication unit communicating with the sixth and eighth liquid chambers, while the fourth communication unit communicating with the fifth and fourth liquid chambers.

18. The multi-outlet-inlet laminated liquid-cooling heat dissipation structure as claimed in claim 17, wherein the communication passages include a first communication passage, a second communication passage, a third communication passage, a fourth communication passage, a fifth communication passage, a sixth communication passage, a seventh communication passage and an eighth communication passage, the first communication passage communicating with the first liquid chamber, the second communication passage communicating with the second liquid chamber, the third communication passage communicating with the fourth liquid chamber, the fourth communication passage communicating with the eighth liquid chamber, the fifth communication passage communicating with the fifth liquid chamber, the sixth communication passage communicating with the sixth liquid chamber, the seventh communication passage communicating with the third liquid chamber, while the eighth communication passage communicating with the seventh liquid chamber.

19. The multi-outlet-inlet laminated liquid-cooling heat dissipation structure as claimed in claim 17, wherein a first flow way, a second flow way, a third flow way, a fourth flow way, a fifth flow way, a sixth flow way, a seventh flow way and an eighth flow way are respectively disposed in the first, second, third, fourth, fifth, sixth, seventh and eighth liquid chambers, the first, second, fifth and sixth flow ways being windingly formed on the lower face of the substrate proximal to the lower liquid chamber, the third, fourth, seventh and eighth flow ways being windingly formed on the upper face of the substrate proximal to the upper liquid chamber as a flow path for guiding the working fluid.

20. The multi-outlet-inlet laminated liquid-cooling heat dissipation structure as claimed in claim 17, further comprising a first pump disposed in any of the first and third liquid chambers, a second pump disposed in any of the second and seventh liquid chambers, a third pump disposed in any of the fifth and fourth liquid chambers and a fourth pump disposed in any of the sixth and eighth liquid chambers.

21. The multi-outlet-inlet laminated liquid-cooling heat dissipation structure as claimed in claim 2, wherein the communication passages include a first communication passage with a first communication opening and a second communication passage with a second communication opening respectively in communication with the lower liquid chamber, the communication passages further including a third communication passage with a third communication opening in communication with the upper liquid chamber.

22. The multi-outlet-inlet laminated liquid-cooling heat dissipation structure as claimed in claim 21, further comprising a pump disposed in any of the upper liquid chamber, the lower liquid chamber and the communication passages.

23. The multi-outlet-inlet laminated liquid-cooling heat dissipation structure as claimed in claim 2, further comprising a pump disposed in any of the upper liquid chamber, the lower liquid chamber and the communication passages.
